(19) United States
(12) Patent Application Publication
(10) Pub. No.: US 2025/0151566 A1
(43) Pub. Date: May 8, 2025

(54) LIGHT EMISSION DEVICE AND IMAGE DISPLAY APPARATUS

(71) Applicant: SONY GROUP CORPORATION, TOKYO (JP)

(72) Inventors: TOSHIO FUJINO, TOKYO (JP); TOSHIHIKO WATANABE, TOKYO (JP); AKIRA OHMAE, TOKYO (JP); MIKIO TAKIGUCHI, TOKYO (JP); HIROSHI MOTOMURO, TOKYO (JP)

(21) Appl. No.: 18/838,101

(22) PCT Filed: Dec. 27, 2022
(86) PCT No.: PCT/JP2022/048328

§ 371 Date: Aug. 13, 2024

(30) Foreign Application Priority Data
Feb. 22, 2022 (JP) 2022-026045

(51) Int. Cl. H10K 59/38; H10K 59/80

(52) U.S. Cl. CPC H10K 59/38; H10K 59/8791

(57) ABSTRACT

A light emission device (1) includes a light emitting element (3) having a light emission surface (3A), a first light controller (41) that is formed on the light emission surface (3A) and controls at least one of a wavelength of light, a diffusion of light, or a direction of light, a covering part (5) that is formed on an opposite side to the light emission surface (3A) of the first light controller (41) and covers and protects the first light controller (41), and a first light shielding part (6) that is formed on a side surface of the covering part (5) and shields light.

### TECHNICAL FIELD

The present disclosure relates to a light emission device and an image display apparatus.

### BACKGROUND ART

PTL 1 below discloses an image display device. In the image display device, a wavelength converter is disposed on a micro light emitting element, and a bulkhead is formed on side surfaces of the micro light emitting element and the wavelength converter. For the micro light emitting element, a light emitting diode (LED: light emitting diode) is used. The wavelength converter converts excitation light emitted from the micro light emitting element into long-wavelength light having a longer wavelength than a wavelength of the excitation light. The bulkhead suppresses a crosstalk of light between adjacent pixels.

The image display device configured in this way attracts attention is a next-generation high-luminance compact display. For example, application to a head mounted display (HMD: Head Mounted Display) such as augmented reality (AR: Augmented Reality) glasses or virtual reality (VR: Virtual Reality) goggles has been expected.

### CITATION LIST

### Patent Literature

PTL 1: Japanese Unexamined Patent Application Publication No. 2020-181980

### SUMMARY OF THE INVENTION

Incidentally, for an image display device, it has been desired to develop a technology for improving a wavelength conversion characteristic of pixels while effectively suppressing or preventing a crosstalk between the pixels.

A light emission device according to a first embodiment of the present disclosure includes a light emitting element having a light emission surface, a first light controller that is formed on the light emission surface and controls at least one of a wavelength of light, a diffusion of light, or a direction of light, a covering part that is formed on an opposite side to the light emission surface of the first light controller and covers and protects the first light controller, and a first light shielding part that is formed on a side surface of the covering part and shields light.

An image display apparatus according to a second embodiment of the present disclosure includes a plurality of arranged light emission devices, and the light emission device includes a light emitting element having a light emission surface, a light controller that is formed on the light emission surface and controls at least one of a wavelength of light, a diffusion of light, or a direction of light, a covering part that is formed on an opposite side to the light emission surface of the light controller and covers and protects the light controller, and a light shielding part that is formed on a side surface of the covering part and shields light.

### BRIEF DESCRIPTION OF DRAWING

FIG. 1 is a main part cross-sectional diagram of a light emission device and an image display apparatus according to a first embodiment of the present disclosure.

FIG. 2 is a main part cross-sectional diagram, corresponding to FIG. 1, for describing optical characteristics of the light emission device and the image display apparatus according to the first embodiment.

FIG. 3A is a main part plan view for describing the optical characteristics of the light emission device and the image display apparatus illustrated in FIG. 2.

FIG. 3B is a main part plan view corresponding to FIG. 3A.

FIG. 4 is a graph for describing the optical characteristics of the light emission device and the image display apparatus according to the first embodiment.

FIG. 5 is a main part cross-sectional diagram, corresponding to FIG. 2, for describing optical characteristics of a light emission device and an image display apparatus according to a comparative example.

FIG. 6 is a graph for describing the optical characteristics of the light emission device and the image display apparatus according to the comparative example.

FIG. 7 is a first process cross-sectional diagram for describing a method for manufacturing the light emission device and the image display apparatus according to the first embodiment.

FIG. 8 is a second process cross-sectional diagram.

FIG. 9 is a third process cross-sectional diagram.

FIG. 10 is a fourth process cross-sectional diagram.

FIG. 11 is a fifth process cross-sectional diagram.

FIG. 12 is a sixth process cross-sectional diagram.

FIG. 13 is a seventh process cross-sectional diagram.

FIG. 14 is a main part cross-sectional diagram, corresponding to FIG. 1, of a light emission device and an image display apparatus according to a second embodiment of the present disclosure.

FIG. 15 is a first process cross-sectional diagram for describing a method for manufacturing the light emission device and the image display apparatus according to the second embodiment.

FIG. 16 is a second process cross-sectional diagram.

FIG. 17 is a third process cross-sectional diagram.

FIG. 18 is a fourth process cross-sectional diagram.

FIG. 19 is a fifth process cross-sectional diagram.

FIG. 20 is a sixth process cross-sectional diagram.

FIG. 21 is a main part cross-sectional diagram, corresponding to FIG. 1, of a light emission device and an image display apparatus according to a third embodiment of the present disclosure.

FIG. 22 is a first process cross-sectional diagram for describing a method for manufacturing the light emission device and the image display apparatus according to the third embodiment.

FIG. 23 is a second process cross-sectional diagram.

FIG. 24 is a main part cross-sectional diagram, corresponding to FIG. 1, of a light emission device and an image display apparatus according to a fourth embodiment of the present disclosure.

FIG. 25 is a main part cross-sectional diagram, corresponding to FIG. 1, of a light emission device and an image display apparatus according to a fifth embodiment of the present disclosure.

FIG. 26 is a main part cross-sectional diagram, corresponding to FIG. 1, of a light emission device and an image display apparatus according to a sixth embodiment of the present disclosure.

FIG. 27 is a main part cross-sectional diagram, corresponding to FIG. 1, of a light emission device and an image display apparatus according to a seventh embodiment of the present disclosure.

FIG. 28 is a main part cross-sectional diagram, corresponding to FIG. 1, of a light emission device and an image display apparatus according to an eighth embodiment of the present disclosure.

FIG. 29 is a main part cross-sectional diagram, corresponding to FIG. 1, of a light emission device and an image display apparatus according to a ninth embodiment of the present disclosure.

FIG. 30 is a first process cross-sectional diagram for describing a method for manufacturing the light emission device and the image display apparatus according to the ninth embodiment.

FIG. 31 is a second process cross-sectional diagram.

FIG. 32 is a third process cross-sectional diagram.

FIG. 33 is a fourth process cross-sectional diagram.

FIG. 34 is a fifth process cross-sectional diagram.

FIG. 35 is a sixth process cross-sectional diagram.

FIG. 36 is a seventh process cross-sectional diagram.

FIG. 37 is an eighth process cross-sectional diagram.

FIG. 38 is a main part cross-sectional diagram, corresponding to FIG. 1, of a light emission device and an image display apparatus according to a tenth embodiment of the present disclosure.

FIG. 39 is a main part cross-sectional diagram, corresponding to FIG. 1, of a light emission device and an image display apparatus according to an eleventh embodiment of the present disclosure.

FIG. 40 is a main part cross-sectional diagram, corresponding to FIG. 1, of a light emission device and an image display apparatus according to a twelfth embodiment of the present disclosure.

FIG. 41 is a main part cross-sectional diagram, corresponding to FIG. 1, of a light emission device and an image display apparatus according to a thirteenth embodiment of the present disclosure.

FIG. 42 is a main part cross-sectional diagram, corresponding to FIG. 1, of a light emission device and an image display apparatus according to a fourteenth embodiment of the present disclosure.

FIG. 43 is a main part cross-sectional diagram, corresponding to FIG. 1, of a light emission device and an image display apparatus according to a modification example of the fourteenth embodiment.

FIG. 44 is a main part cross-sectional diagram, corresponding to FIG. 1, of a light emission device and an image display apparatus according to a fifteenth embodiment of the present disclosure.

FIG. 45 is a main part cross-sectional diagram, corresponding to FIG. 1, of a light emission device and an image display apparatus according to a sixteenth embodiment of the present disclosure.

FIG. 46 is a main part cross-sectional diagram, corresponding to FIG. 1, of a light emission device and an image display apparatus according to a seventeenth embodiment of the present disclosure.

FIG. 47 is a main part cross-sectional diagram, corresponding to FIG. 1, of a light emission device and an image display apparatus according to an eighteenth embodiment of the present disclosure.

FIG. 48 is a main part cross-sectional diagram, corresponding to FIG. 1, of a light emission device and an image display apparatus according to a nineteenth embodiment of the present disclosure.

FIG. 49 is a main part cross-sectional diagram, corresponding to FIG. 1, of a light emission device and an image display apparatus according to a twentieth embodiment of the present disclosure.

FIG. 50 is a main part cross-sectional diagram, corresponding to FIG. 1, of a light emission device and an image display apparatus according to a twenty-first embodiment of the present disclosure.

FIG. 51 is a main part cross-sectional diagram, corresponding to FIG. 1, of a light emission device and an image display apparatus according to a twenty-second embodiment of the present disclosure.

FIG. 52 is a main part cross-sectional diagram, corresponding to FIG. 1, of a light emission device and an image display apparatus according to a twenty-third embodiment of the present disclosure.

### MODES FOR CARRYING OUT THE INVENTION

Hereinafter, embodiments of the present disclosure are described in detail with reference to the drawings. It is to be noted that the description is given in the following order.

### 1. First Embodiment

The first embodiment describes an example in which the present technology is applied to a light emission device and an image display apparatus. Here, a basic structure and a manufacturing method of the light emission device and the image display apparatus are described.

### 2. Second Embodiment

The second embodiment describes a first (1) example in which structures of a pixel separator and a light shielding part (first light shielding part) are changed, in the light emission device and the image display apparatus according to the first embodiment. The second embodiment also describes a basic structure and a manufacturing method of the light emission device and the image display apparatus, as in the first embodiment.

### 3. Third Embodiment

The third embodiment describes an example in which the light emission device and the image display apparatus according to the first embodiment and the light emission device and the image display apparatus according to the second embodiment are combined. The third embodiment also describes a basic structure and a manufacturing method of the light emission device and the image display apparatus, as in the first embodiment.

### 4. Fourth Embodiment

The fourth embodiment describes a first (2) example in which structures of a pixel separator and a light shielding part (first light shielding part) are changed, in the light emission device and the image display apparatus according to the first embodiment.

### 5. Fifth Embodiment

The fifth embodiment describes a first (3) example in which structures of a pixel separator and a light shielding part (first light shielding part) are changed, in the light emission device and the image display apparatus according to the fourth embodiment.

### 6. Sixth Embodiment

The sixth embodiment describes a first (4) example in which structures of a pixel separator and a light shielding part (first light shielding part) are changed, in the light emission device and the image display apparatus according to the fourth embodiment.

### 7. Seventh Embodiment

The seventh embodiment describes a first (5) example in which structures of a pixel separator and a light shielding part (first light shielding part) are changed, in the light emission device and the image display apparatus according to the fourth embodiment.

### 8. Eighth Embodiment

The eighth embodiment describes a first (6) example in which structures of a pixel separator and a light shielding part (first light shielding part) are changed, in the light emission device and the image display apparatus according to the fourth embodiment.

### 9. Ninth Embodiment

The ninth embodiment describes a first (7) example in which structures of a pixel separator and a light shielding part (first light shielding part) are changed, in the light emission device and the image display apparatus according to the fourth embodiment. The ninth embodiment also describes a basic structure and a manufacturing method of the light emission device and the image display apparatus, as in the first embodiment.

### 10. Tenth Embodiment

The tenth embodiment describes a first (8) example in which structures of a pixel separator and a light shielding part (first light shielding part) are changed, in the light emission device and the image display apparatus according to the eighth embodiment.

### 11. Eleventh Embodiment

The eleventh embodiment describes a second (1) example in which the light emission device and the image display apparatus according to the first embodiment and the light emission device and the image display apparatus according to the fourth embodiment are combined and a plurality of pixels each including a single wavelength converter is arranged.

### 12. Twelfth Embodiment

The twelfth embodiment describes a second (2) example in which a pixel including a transparent part is further arranged, in the light emission device and the image display apparatus according to the eleventh embodiment.

### 13. Thirteenth Embodiment

The thirteenth embodiment describes a second (3) example in which a pixel including two types of light controllers is arranged, in the light emission device and the image display apparatus according to the twelfth embodiment.

### 14. Fourteenth Embodiment

The fourteenth embodiment describes a third (1) example in which configurations of a covering part and a light controller are changed, in the light emission device and the image display apparatus according to the twelfth embodiment or the thirteenth embodiment.

### 15. Fifteenth Embodiment

The fifteenth embodiment describes a third (2) example in which a pixel including three types of light controllers is arranged, in the light emission device and the image display apparatus according to the fourteenth embodiment.

### 16. Sixteenth Embodiment

The sixteenth embodiment describes a third (3) example in which a configuration of a covering part is changed, in the light emission device and the image display apparatus according to the thirteenth embodiment.

### 17. Seventeenth Embodiment

The seventeenth embodiment describes a third (4) example in which a covering part includes a plurality of different types of layers, in the light emission device and the image display apparatus according to the fourteenth embodiment.

### 18. Eighteenth Embodiment

The eighteenth embodiment describes a third (5) example, in which a configuration of a covering part is changed, in the light emission device and the image display apparatus according to the seventeenth embodiment.

### 19. Nineteenth Embodiment

The nineteenth embodiment describes a fourth (1) example in which a dielectric multi-layer film is further disposed in a covering part, in the light emission device and the image display apparatus according to the fourteenth embodiment.

### 20. Twentieth Embodiment

The twentieth embodiment describes a fourth (2) example, in which an optical path controller is further disposed in a covering part, in the light emission device and the image display apparatus according to the nineteenth embodiment.

### 21. Twenty-First Embodiment

The twenty-first embodiment describes a fourth (3) example in which a color filter is disposed in a covering part, in the light emission device and the image display apparatus according to any one of the eleventh to fifteenth embodiments.

### 22. Twenty-Second Embodiment

The twenty-second embodiment describes an example in which a configuration of a light emitting element is changed, in the light emission device and the image display apparatus according to any one of the first to twenty-first embodiments.

### 23. Twenty-Third Embodiment

The twenty-third embodiment describes an example of a preferred light emission device and image display apparatus.

### 24. Other Embodiments

### 1. First Embodiment

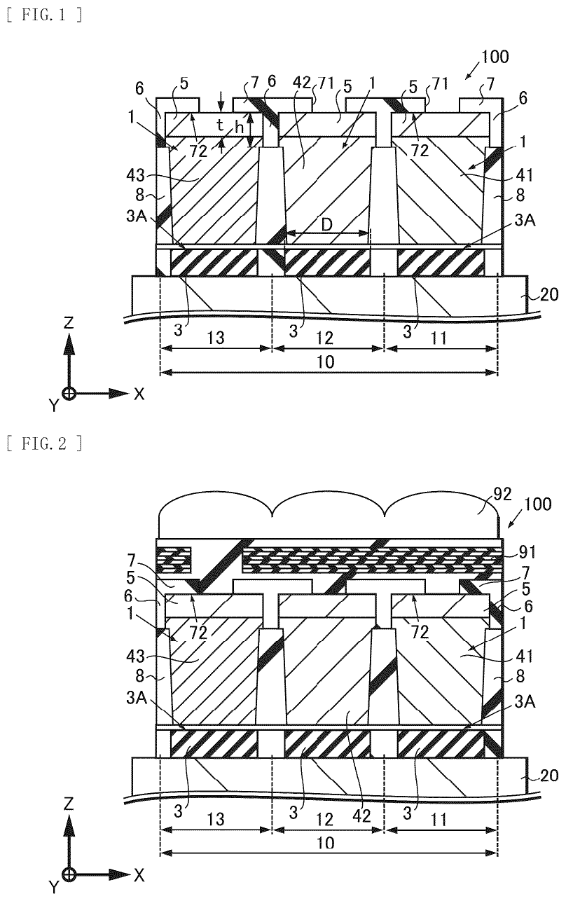

A light emission device 1 and an image display apparatus 100 according to the first embodiment of the present disclosure are described with reference to FIGS. 1 to 13.

Here, an arrow X direction appropriately illustrated in the drawings conveniently indicates a single planar direction of the light emission device 1 and the image display apparatus 100 placed on a plane. An arrow Y direction indicates another planar direction orthogonal to the arrow X direction. Furthermore, an arrow Z direction indicates an upward direction orthogonal to the arrow X direction and the arrow Y direction. That is, the arrow X direction, the arrow Y direction, and the arrow Z direction exactly and respectively match an X-axis direction, a Y-axis direction, and a Z-axis direction of a three-dimensional coordinate system.

Note that these directions are illustrated for easy understanding of description, and do not limit directions of the present technology.

### [Configuration of Light Emission Device 1 and Image Display Apparatus 100]

### (1) Schematic Overall Configuration of Light Emission Device 1 and Image Display Apparatus 100

FIG. 1 illustrates an example of a vertical cross-sectional configuration of the light emission device 1 and the image display apparatus 100.

The image display apparatus 100 according to the first embodiment includes the plurality of arranged light emission devices 1. Here, the plurality of light emission devices 1 is arranged in each of the arrow X direction and the arrow Y direction. Furthermore, the light emission devices 1 arranged in the arrow X direction are disposed to be displaced by an arrangement pitch that is a half of an arrangement pitch of the light emission device 1, with respect to the light emission devices 1 arranged in another arrow X direction adjacent in the arrow Y direction.

Furthermore, the light emission device 1 configures a first pixel 11, a second pixel 12, or a third pixel 13 as a subpixel. Here, the first pixel 11 is a pixel that emits red light. The second pixel 12 is a pixel that emits green light. The third pixel 13 is a pixel that emits blue light.

Here, the single first pixel 11, the single second pixel 12, and the single third pixel 13 construct a color pixel 10 that makes it possible to display a color image.

Note that, for easy understanding, in the present disclosure, a color of light emitted from each of the first pixel 11, the second pixel 12, and the third pixel 13 is typically specified. The present disclosure is not limited to the description here, and for example, the first pixel 11 may be a pixel that emits the green light or the blue light. Furthermore, the second pixel 12 may be a pixel that emits the red light or the blue light. Moreover, the third pixel 13 may be a pixel that emits the red light or the green light.

The light emission device 1 is disposed on a substrate 20. Then, the first pixel 11 including the light emission device 1 includes a light emitting element 3, a first light controller 41, a covering part 5, and a first light shielding part 6 as main components. Furthermore, the second pixel 12 includes the light emitting element 3, a second light controller 42, the covering part 5, and the first light shielding part 6 as main components. Similarly, the third pixel 13 includes the light emitting element 3, a third light controller 43, the covering part 5, and the first light shielding part 6 as main components.

Here, each of the first light controller 41, the second light controller 42, and the third light controller 43 may be simply referred to as a “light controller”. Furthermore, the first light shielding part 6 may be simply referred to as a “light shielding part”.

Moreover, the light emission device 1 includes a second light shielding part 7, a dielectric multi-layer film 91 to be described in a light emission device 1 and an image display apparatus 100 according to the nineteenth embodiment, and an optical path controller 92 to be described in a light emission device 1 and an image display apparatus 100 according to the twentieth embodiment (refer to FIG. 2).

### (2) Configuration of Substrate 20

The substrate 20 is a substrate common to the plurality of arranged light emission devices 1 or the plurality of arranged color pixels 10. Similarly, the substrate 20 is a substrate of the image display apparatus 100. In the substrate 20, a driving circuit (not illustrated) that drives the light emission device 1 is disposed.

The substrate 20 includes, for example, a semiconductor substrate such as a single crystal silicon (Si) substrate, a glass substrate, or a glass epoxy substrate.

### (3) Configuration of Light Emitting Element 3

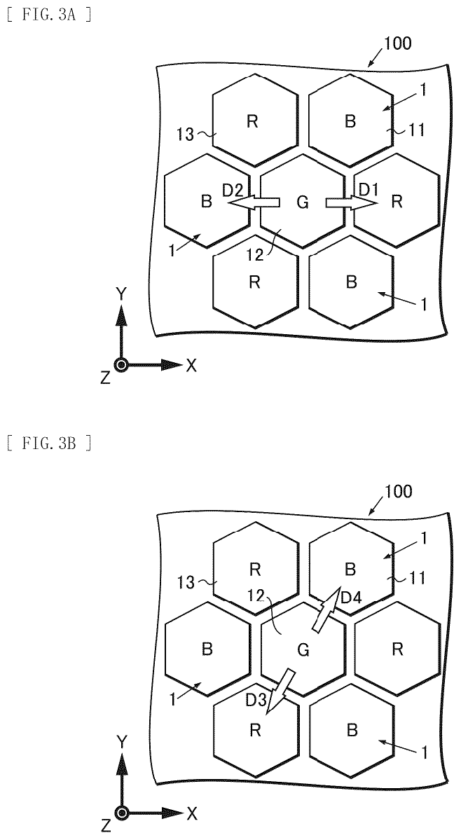

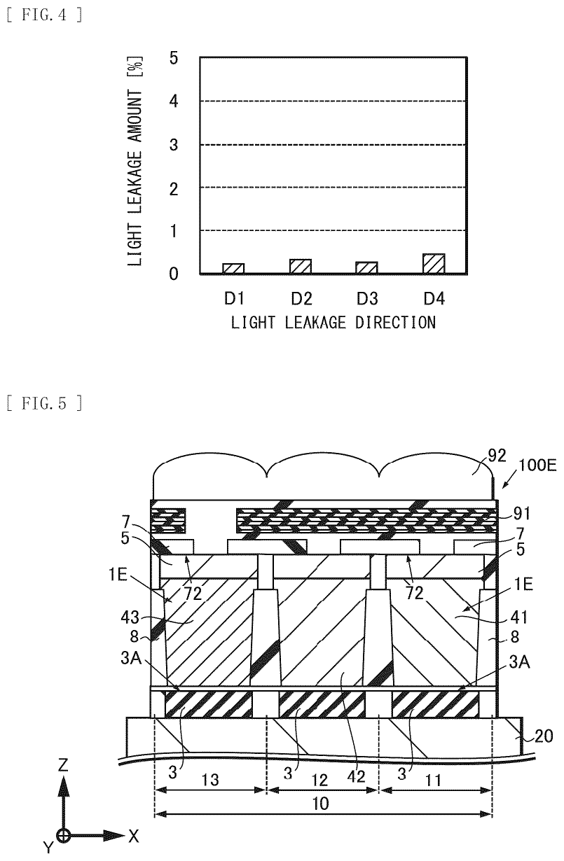

For the light emitting element 3, a self-luminous-type light source is used. The light emitting element 3 is formed here in a polygonal shape as viewed from the arrow Z direction (hereinafter, simply referred to as “planar view”) and is formed in a layer form (simplified) as viewed from the arrow Y direction (hereinafter, simply referred to as “side view”). The light emitting element 3 is formed in a hexagonal shape in the first embodiment (refer to FIGS. 3A and 3B).

A top surface of the light emitting element 3 in the arrow Z direction is a light emission surface 3A. The light emitting element 3 isotropically emits light upward from the light emission surface 3A. Here, on a plane extending in the arrow X direction or the arrow Y direction, a light-emitting diameter D of the light emission surface 3A is a diameter dimension of a region where light is effectively emitted.

Note that the light emitting element 3 may be formed in a polygonal shape, excluding a circular shape, an elliptical shape, and a hexagonal shape in planar view.

Here, the light emitting element 3 is formed by an LED, for example. The LED is formed by a group III-V compound semiconductor (inorganic compound semiconductor).

Note that the light emitting element 3 may be a Light Amplification by Stimulated Emission of Radiation (LASER) similarly formed by a compound semiconductor.

### (4) Configuration of First Light Controller 41, Second Light Controller 42, and Third Light Controller 43

The first light controller 41 is disposed on the light emission surface 3A of the light emitting element 3 in the first pixel 11. The light emission surface 3A is a surface on an opposite side to the substrate 20 of the light emitting element 3. In the first embodiment, the first light controller 41 includes a light wavelength conversion material that controls (convert) a wavelength of light. That is, in the first light controller 41, light emitted from the light emission surface 3A is absorbed, and a wavelength of the absorbed light is converted. The light of which the wavelength has been converted is outputted from the first light controller 41 as fluorescence excitation light. For example, the first light controller 41 converts blue light emitted from the light emission surface 3A into red light and outputs the red light.

Similarly, the second light controller 42 is disposed on the light emission surface 3A of the light emitting element 3 in the second pixel 12. The second light controller 42 converts the blue light into green light different from that of the first light controller 41. The third light controller 43 is disposed on the light emission surface 3A of the light emitting element 3 in the third pixel 13. The third light controller 43 converts the blue light into blue light different from that of each of the first light controller 41 and the second light controller 42.

Each of the first light controller 41, the second light controller 42, and the third light controller 43 includes the light wavelength conversion material. As the light wavelength conversion material, for example, it is possible to use nanoparticles such as an inorganic phosphor, an organic phosphor, a quantum dot, or a quantum rod.

### (5) Configuration of Pixel Separator 8

A pixel separator 8 is disposed between the first pixel 11, the second pixel 12, and the third pixel 13. The pixel separator 8 is formed along a side surface of each of the first light controller 41, the second light controller 42, and the third light controller 43 and disposed between each controller. For example, the pixel separator 8 has a configuration that shields light (leaked light) from the second light controller 42 to the first light controller 41 or the third light controller 43.

Here, the pixel separator 8 includes, for example, silicon oxide (SiO), silicon nitride (SiN), or a metal material. As the metal material, specifically, it is possible to practically use one or more metal materials selected from among aluminum (Al), silver (Ag), gold (Au), platinum (Pt), copper (Cu), and titanium (Ti). Furthermore, the pixel separator 8 may be one in which a metal material with a high reflectance is formed on a surface of SiO or SiN.

### (6) Configuration of Covering Part 5

The covering part 5 is formed to cover the first light controller 41, on an opposite side to the light emission surface 3A of the first light controller 41, in the first pixel 11. Here, the covering part 5 is stacked on the first light controller 41 in direct contact with the first light controller 41.

Similarly, the covering part 5 is formed to cover the second light controller 42, on an opposite side to the light emission surface 3A of the second light controller 42, in the second pixel 12. Moreover, the covering part 5 is formed to cover the third light controller 43, on an opposite side to the light emission surface 3A of the third light controller 43, in the third pixel 13.

The covering part 5 protects at least a surface region of each of the first light controller 41, the second light controller 42, and the third light controller 43.

More specifically, in a method for manufacturing the light emission device 1 and the image display apparatus 100, the covering part 5 protects the first light controller 41, the second light controller 42, and the third light controller 43, with respect to processing to be executed after the first light controller 41, the second light controller 42, and the third light controller 43 have been formed. The processing to be executed after the first light controller 41 or the like has been formed is, for example, etching processing such as dry etching processing. Furthermore, this processing is, for example, polishing processing such as chemical mechanical polishing (CMP: Chemical Mechanical Polishing) processing.

The covering part 5 includes a material that is usable as a protection film, more particularly, a material not for an optical orientation adjustment purpose, that is, a material having moisture resistance and oxygen resistance. For example, for the covering part 5, at least one material selected from among Al₂O₃, SiO, SiN, a silicon resin, a siloxane resin, and an acryl resin is used. When Al₂O₃ is selected, a film thickness of the covering part 5 is equal to or more than 10 nm and equal to or less than 100 nm. Furthermore, for example, when SiO is selected, the film thickness of the covering part 5 is equal to or more than 100 nm and equal to or less than 1000 nm. It is possible for the covering part 5 to which this film thickness is set to effectively suppress or prevent a damage for impairing wavelength conversion characteristics to be given to the first light controller 41, the second light controller 42, and the third light controller 43, with respect to the above processing.

Furthermore, for the covering part 5, it is possible to use a light wavelength conversion material having a different quantum dot density from the first light controller 41 or the like.

### (7) Configuration of Second Light Shielding Part 7

On an opposite side to the light emission surface 3A of the covering part 5, the second light shielding part 7 is disposed. The second light shielding part 7 is formed in a plate-like shape or a layer shape in side view and has an opening 71 that passes through an intermediate portion in a thickness direction.

The second light shielding part 7 shields light emitted from the light emission surface 3A. In the first embodiment, the second light shielding part 7 is also formed as a first reflection region 72 that reflects or diffuses the light emitted from the light emission surface 3A toward the light emission surface 3A.

The second light shielding part 7 includes a metal material with excellent light reflection characteristics, for example, aluminum (Al). Moreover, it is possible to use silver (Ag), gold (Au), platinum (Pt), copper (Cu), titanium (Ti), or the like for the second light shielding part 7, as the metal material with the excellent light reflection characteristics.

Furthermore, at least a portion of the second light shielding part 7 on the side of the light emission surface 3A may be configured as the first reflection region 72. For example, the second light shielding part 7 may be formed using a metal material, an inorganic material, or a resin material having a lower reflectance than Al as a base, and a metal material with a high reflectance may be formed on a surface of these materials.

Moreover, the second light shielding part 7 may include a resin that does not transmit light, for example, a resin material including black ink. In this case, the second light shielding part 7 does not function as the first reflection region.

The single opening 71 of the second light shielding part 7 is disposed for the single light emitting element 3. In the first embodiment, the opening 71 is formed to have a similar opening shape to the shape of the light emission surface 3A in planar view. An opening dimension of the opening 71 is set to be a dimension smaller than the light-emitting diameter D of the light emission surface 3A. Furthermore, a center position of the opening 71 is fitted on an optical axis of the light emission device 1.

The opening 71 transmits the light emitted from the light emission surface 3A and controlled by the first light controller 41, the second light controller 42, or the third light controller 43. Moreover, the opening 71 transmits the light reflected by the first reflection region 72 and controlled by the first light controller 41, the second light controller 42, or the third light controller 43 again.

Note that, the opening shape of the opening 71 may be different from the shape of the light emission surface 3A. For example, it is possible to form the opening shape in a polygonal shape except for a circular shape, an elliptical shape, and a hexagonal shape.

### (8) Configuration of First Light Shielding Part 6

The first light shielding part 6 is formed along the side surface of the covering part 5. The first light shielding part 6 is disposed between the adjacent light emission devices 1. The first light shielding part 6 shields, for example, light (leaked light) from the covering part 5 of the second pixel 12 to the covering part 5 of the first pixel 11 or the covering part 5 of the third pixel 13.

In the first embodiment, the first light shielding part 6 includes the same material as the second light shielding part 7 and is formed integrally with the second light shielding part 7. That is, the first light shielding part 6 and the second light shielding part 7 are continuously formed from the side surface of the covering part 5 to the top surface of the covering part 5.

Furthermore, the first light shielding part 6 is formed in contact with an upper portion of the pixel separator 8. Furthermore, the first light shielding part 6 is extended along the side surface from the top surface of the covering part 5, and in addition, to each of positions between the first light controller 41, the second light controller 42, and the third light controller 43. In other expression, a dimension of a height h (dimension in arrow Z direction) of the first light shielding part 6 is larger than a dimension of a thickness t (dimension in arrow Z direction) of the covering part 5. As a result, the first light shielding part 6 is formed in a shape digging into the upper portion of the pixel separator 8, in side view.

### (1) Optical Characteristics of Light Emission Device 1 and Image Display Apparatus 100

Next, light crosstalk characteristics of the light emission device 1 and the image display apparatus 100 according to the first embodiment are described.

### (1) Optical Characteristics of Light Emission Device 1E and Image Display Apparatus 100E According to Comparative Example

FIG. 5 illustrates an example of a vertical cross-sectional configuration of a light emission device 1E and an image display apparatus 100E according to a comparative example.

In the light emission device 1E and the image display apparatus 100E, a first light shielding part 6 is not disposed along a side surface of a covering part 5, with respect to the components of the light emission device 1 and the image display apparatus 100 according to the first embodiment. Components of the light emission device 1E and the image display apparatus 100E other than this are the same as the components of the light emission device 1 and the image display apparatus 100 according to the first embodiment.

Note that, in the light emission device 1E and the image display apparatus 100E, a dielectric multi-layer film 91 of a light emission device 1 and an image display apparatus 100 according to the nineteenth embodiment to be described later and an optical path controller 92 of a light emission device 1 and an image display apparatus 100 according to the twentieth embodiment are disposed. Each of the dielectric multi-layer film 91 and the optical path controller 92 does not substantially have an effect on the crosstalk characteristics

Each of FIGS. 3A and 3B illustrates an example of a planar configuration of the light emission device 1E and the image display apparatus 100E. The planar configuration is the same as the planar configuration of the light emission device 1 and the image display apparatus 100 according to the first embodiment. Here, a reference “R” indicates a first pixel 11 that includes a first light controller 41 and emits red light. A reference “G” indicates a second pixel 12 that includes a second light controller 42 and emits green light. Then, a reference “B” indicates a third pixel 13 that includes a third light controller 43 and emits blue light.

FIG. 3A illustrates a leakage direction D1 of light from the second pixel 12 arranged in the middle toward the first pixel 11 adjacent on the right side. Furthermore, a leakage direction D2 of light from the second pixel 12 arranged in the middle toward the third pixel 13 adjacent on the left side is illustrated. FIG. 3B illustrates a leakage direction D3 of light from the second pixel 12 arranged in the middle toward the first pixel 11 adjacent on an obliquely lower left side. Furthermore, a leakage direction D4 of light from the second pixel 12 arranged in the middle toward the third pixel 13 adjacent on an obliquely upper right side is illustrated.

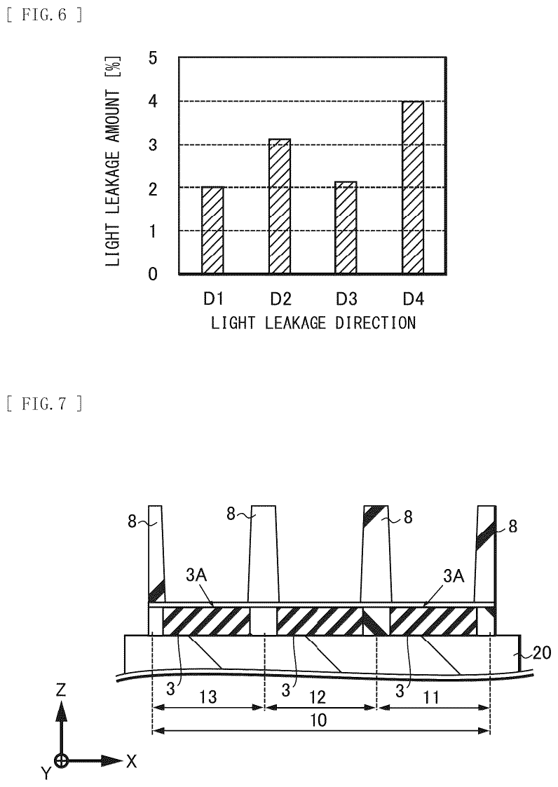

FIG. 6 illustrates a relationship between each of the directions D1 to D4 and a light leakage amount [%] with respect to an output reference value of the light emission device 1E, in the light emission device 1E and the image display apparatus 100E. As illustrated in FIG. 6, each of a leakage amount of about two [%] in the direction D1, a leakage amount of about three [%] in the direction D2, a leakage amount of about two [%] in the direction D3, and a leakage amount of about four [%] in the direction D4 has been confirmed.

### (2) Optical Characteristics of Light Emission Device 1 and Image Display Apparatus 100 According to First Embodiment

FIG. 2 illustrates an example of a vertical cross-sectional configuration of the light emission device 1 and the image display apparatus 100 according to the first embodiment.

In the light emission device 1 and the image display apparatus 100, the first light shielding film 6 is disposed along the side surface of the covering part 5, with respect to the components of the light emission device 1E and the image display apparatus 100E according to the comparative example. Furthermore, the light emission device 1 and the image display apparatus 100 include the dielectric multi-layer film 91 and the optical path controller 92.

FIG. 4 corresponds to FIG. 6 and illustrates a relationship between each of the directions D1 to D4 and the light leakage amount [%] with respect to the output reference value of the light emission device 1, in the light emission device 1 and the image display apparatus 100. As illustrated in FIG. 4, each of a small leakage amount of about 0.2[%] in the direction D1, a small leakage amount of about 0.3[%] in the direction D2, a small leakage amount of about 0.2[%] in the direction D3, and a small leakage amount of about 0.4[%] in the direction D4 has been confirmed.

### [Method for Manufacturing Light Emission Device 1 and Image Display Apparatus 100]

FIGS. 7 to 13 are process cross-sectional diagrams for describing a method for manufacturing the light emission device 1 and the image display apparatus 100 according to the first embodiment. The method for manufacturing the light emission device 1 and the image display apparatus 100 is as follows.

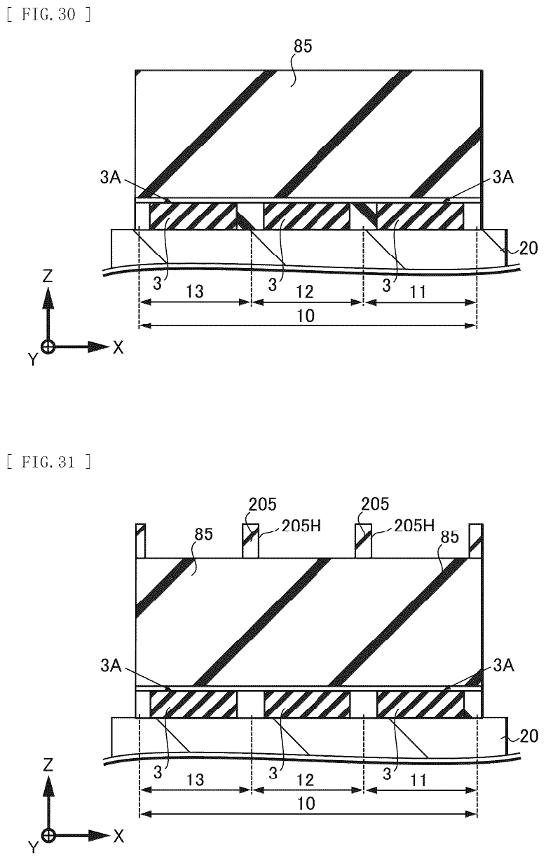

First, as illustrated in FIG. 7, the pixel separator 8 is formed. The pixel separator 8 is formed by forming, for example, an SiO film on the light emitting element 3 of the color pixel 10 and performing patterning for leaving the SiO film between the light emitting elements 3 and removing others (refer to FIGS. 30 to 32, in ninth embodiment). The SiO film is formed, for example, by a chemical vapor deposition (CVD: Chemical Vapor Deposition) method, a sputtering method, or the like. The patterning is performed by using a mask formed by a photolithography technology and, for example, a dry etching method.

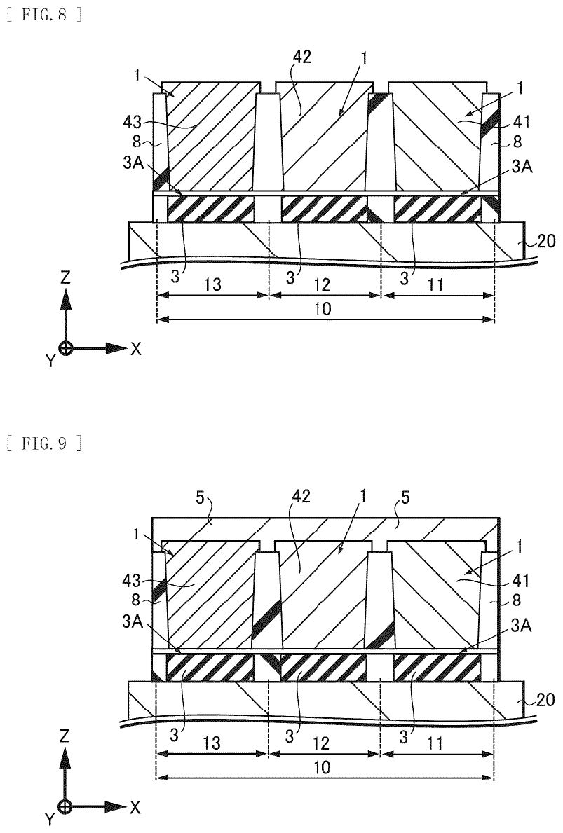

As illustrated in FIG. 8, the first light controller 41, the second light controller 42, and the third light controller 43 are formed. The first light controller 41 is formed on the light emitting element 3 to be the first pixel 11. The second light controller 42 is formed on the light emitting element 3 to be the second pixel 12. Then, the third light controller 43 is formed on the light emitting element 3 to be the third pixel 13. Each of the first light controller 41, the second light controller 42, and the third light controller 43 is formed by the photolithography technology or an ink-jet technology.

As illustrated in FIG. 9, the covering part 5 covering each of the first light controller 41, the second light controller 42, and the third light controller 43 is formed. The covering part 5 includes, for example, a SiO film. The SiO film is formed by the CVD method, the sputtering method, or the like.

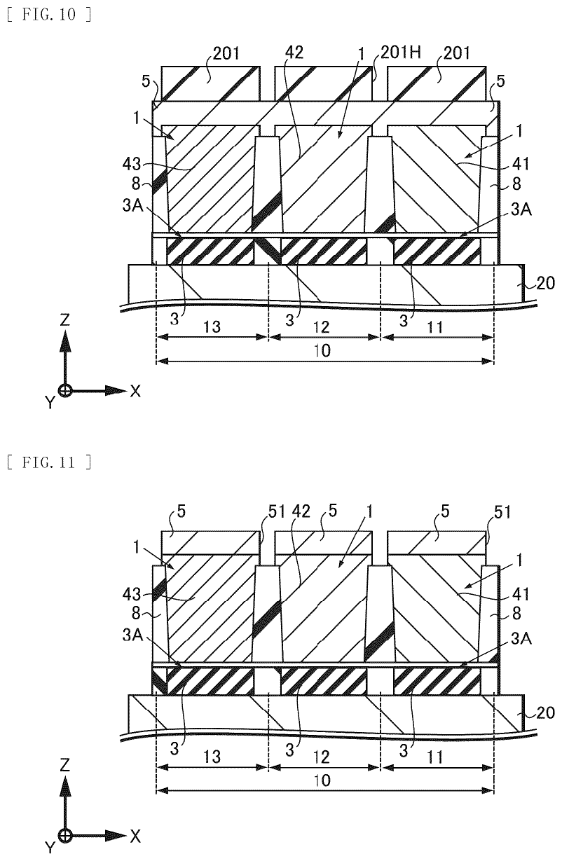

As illustrated in FIG. 10, a mask 201 is formed on the covering part 5. In the mask 201, an opening 201H is formed in a region of the pixel separator 8. The mask 201 is formed, for example, by the photolithography technology.

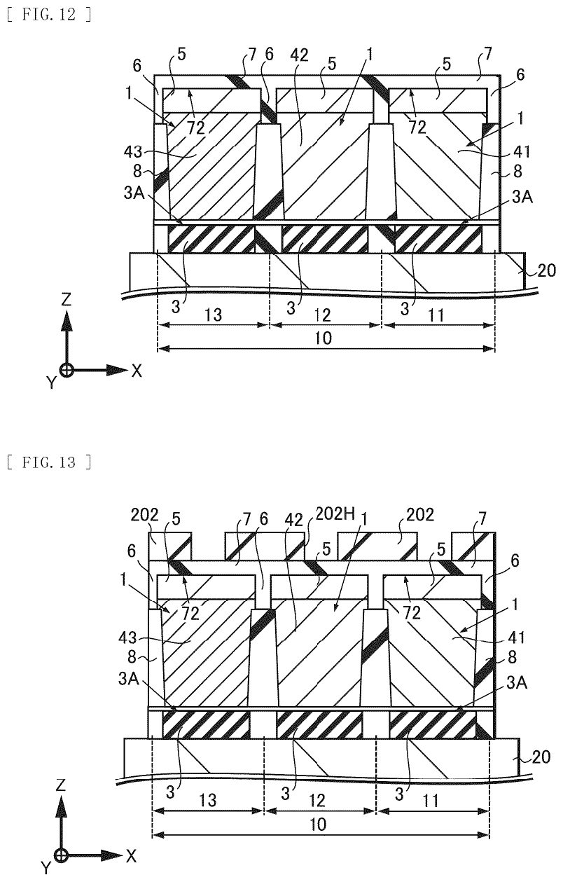

As illustrated in FIG. 11, the covering part 5 is patterned using the mask 201. This patterning separates the covering part 5 for each of the first pixel 11, the second pixel 12, and the third pixel 13, and a side surface 51 of the covering part 5 is exposed. Furthermore, the patterning is performed to the pixel separator 8. For the patterning, for example, the dry etching method is used.

As illustrated in FIG. 12, the first light shielding part 6 is formed on the side surface 51 of the covering part 5, and in addition, the second light shielding part 7 is formed on the covering part 5 in the same manufacturing process. The first light shielding part 6 and the second light shielding part 7 include, for example, Al. Al is formed, for example, by the sputtering method. By using Al, the first light shielding part 6 shields light, and a reflection region (second reflection region) is formed. Similarly, the second light shielding part 7 shields light, and the first reflection region 72 is formed.

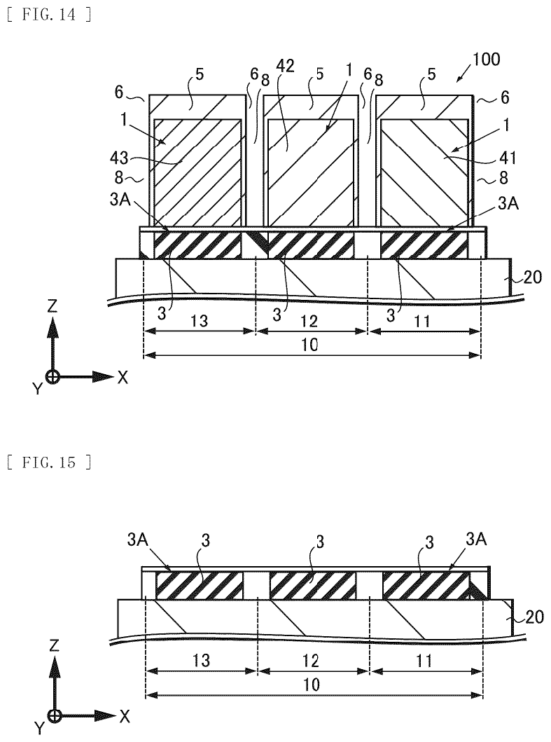

As illustrated in FIG. 13, a mask 202 is formed on the second light shielding part 7. In the mask 202, an opening 202H is formed. The mask 202 is formed, for example, by the photolithography technology.

The second light shielding part 7 exposed from the opening 202H is patterned using the mask 202. As a result, as illustrated in FIG. 1 above, the opening 71 is formed in the second light shielding part 7. For example, the dry etching method is used for the patterning.

When the series of manufacturing processes end, the light emission device 1 and the image display apparatus 100 according to the first embodiment are completed.

### [Workings and Effects]

The light emission device 1 according to the first embodiment includes the light emitting element 3 and the first light controller 41, as illustrated in FIG. 1. The light emitting element 3 has the light emission surface 3A. The first light controller 41 is formed on the light emission surface 3A and controls at least one of the wavelength of light, the diffusion of light, or the direction of light.

Then, the light emission device 1 further includes the covering part 5 and the first light shielding part 6.

The covering part 5 is formed on the opposite side to the light emission surface 3A of the first light controller 41 and covers and protects the first light controller 41. This makes it possible to effectively suppress or prevent a damage on the first light controller 41 by the covering part 5. For example, in the method for manufacturing the light emission device 1, it is possible to effectively suppress or prevent the damage on the first light controller 41 caused by the dry etching method in the process for forming the opening 71 illustrated in FIG. 13.

On the other hand, the first light shielding part 6 is formed on the side surface of the covering part 5 and shields light. This makes it possible to effectively suppress or prevent the leaked light between the adjacent covering parts 5, as illustrated in FIG. 4 above.

The covering part 5 is formed not only on the first light controller 41 but also similarly formed on each of the second light controller 42 and the third light controller 43. Furthermore, the first light shielding part 6 is formed not only on the side surface of the first light controller 41 but also similarly formed on each of the side surface of the second light controller 42 and the side surface of the third light controller 43.

That is, the light emission device 1 makes it possible to improve wavelength conversion characteristics of each of the first pixel 11, the second pixel 12, and the third pixel 13, while effectively suppressing or preventing the crosstalk between each of the first pixel 11, the second pixel 12, and the third pixel 13.

Such workings and effects are similarly obtained in the image display apparatus 100 including the plurality of light emission devices 1 arranged in a regular manner.

Furthermore, the light emission device 1 includes the second light shielding part 7, as illustrated in FIG. 1. The second light shielding part 7 is formed on the opposite side to the light emission surface 3A of the covering part 5, includes the through opening 71 that transmits light, and shields the light emitted from the light emission surface 3A.

Because this makes it possible to efficiently emit the light emitted from the light emission surface 3A of the light emitting element 3 and controlled by the first light controller 41 from the opening 71 of the second light shielding part 7, it is possible to realize high luminance in an emission direction. It is possible to obtain similar workings and effects for the light controlled by each of the second light controller 42 and the third light controller 43.

Furthermore, the light emission device 1 includes the first reflection region 72, as illustrated in FIG. 1. The first reflection region 72 is formed in at least a portion of the second light shielding part 7 on the side of the first light controller 41 and reflects light.

Because this makes it possible to efficiently emit the light, emitted from the light emission surface 3A of the light emitting element 3, reflected by the first reflection region 72, and controlled by the first light controller 41, from the opening 71 of the second light shielding part 7, it is possible to realize higher luminance in the emission direction. It is possible to obtain similar workings and effects for the light controlled by each of the second light controller 42 and the third light controller 43.

Moreover, in the light emission device 1, the second light shielding part 7 includes the same material as the first light shielding part 6, as illustrated in FIGS. 1 and 12.

This makes it possible to easily realize the structures of the first light shielding part 6 and the second light shielding part 7. Furthermore, in the method for manufacturing the light emission device 1 and the image display apparatus 100, it is possible for the process for forming the second light shielding part 7 to serve as the process for forming the first light shielding part 6. Therefore, it is possible to reduce the number of manufacturing processes.

The workings and effects obtained by the light emission device 1 are obtained as similar workings and effects by the image display apparatus 100.

### 2. Second Embodiment

Next, a light emission device 1 and an image display apparatus 100 according to the second embodiment of the present disclosure are described. In the second embodiment and subsequent embodiments, components same as or substantially same as the components of the light emission device 1 and the image display apparatus 100 according to the first embodiment are denoted by the same references, and overlapped description is omitted.

### [Configuration of Light Emission Device 1 and Image Display Apparatus 100]

FIG. 14 illustrates an example of a vertical cross-sectional configuration of the light emission device 1 and the image display apparatus 100.

In the light emission device 1 and the image display apparatus 100 according to the second embodiment, a first light shielding part 6 formed along a side surface of a covering part 5 is an air gap. That is, gas such as air or nitrogen gas is provided between the adjacent first light shielding parts 6.

Moreover, in the light emission device 1 and the image display apparatus 100, similarly to the first light shielding part 6, a pixel separator 8 is an air gap.

Note that, in the light emission device 1 and the image display apparatus 100 according to the second embodiment, the second light shielding part 7 in the light emission device 1 and the image display apparatus 100 according to the first embodiment is not disposed. Components other than the above components are the same as the components of the light emission device 1 and the image display apparatus 100 according to the first embodiment.

### [Method for Manufacturing Light Emission Device 1 and Image Display Apparatus 100]

FIGS. 15 to 20 are process cross-sectional diagrams for describing a method for manufacturing the light emission device 1 and the image display apparatus 100 according to the second embodiment. The method for manufacturing the light emission device 1 and the image display apparatus 100 is as follows.

First, as illustrated in FIG. 15, a light emitting element 3 is formed in a region of each of a first pixel 11, a second pixel 12, and a third pixel 13 of a color pixel 10.

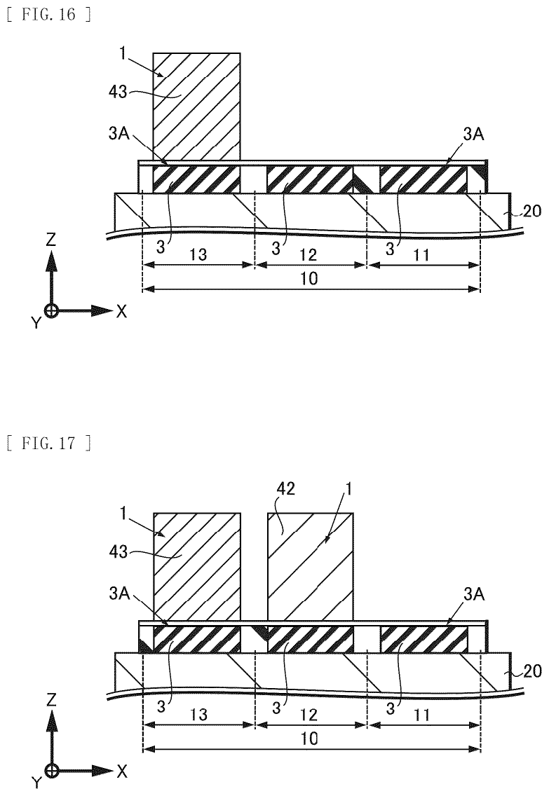

As illustrated in FIG. 16, a third light controller 43 is formed on the light emitting element 3 to be the third pixel 13. Subsequently, as illustrated in FIG. 17, a second light controller 42 is formed on the light emitting element 3 to be the second pixel 12. Then, as illustrated in FIG. 18, a first light controller 41 is formed on the light emitting element 3 to be the first pixel 11.

Here, a space where the pixel separator 8 is arranged is formed between the first light controller 41, the second light controller 42, and the third light controller 43.

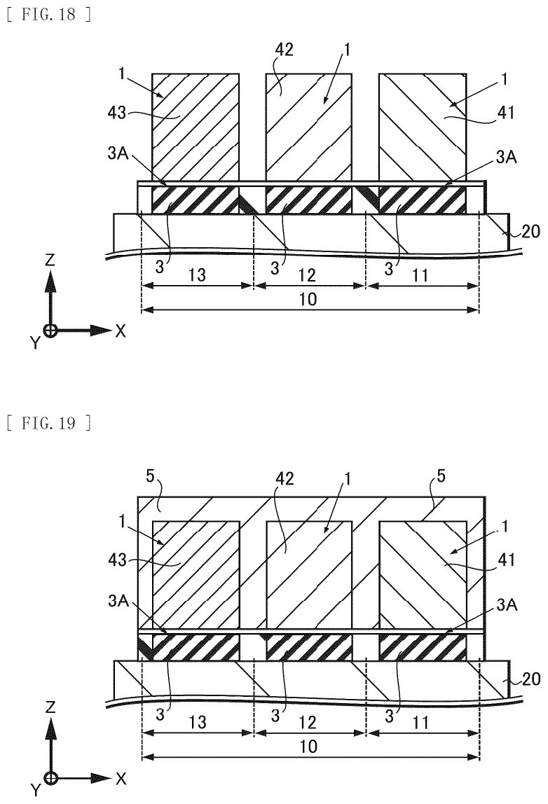

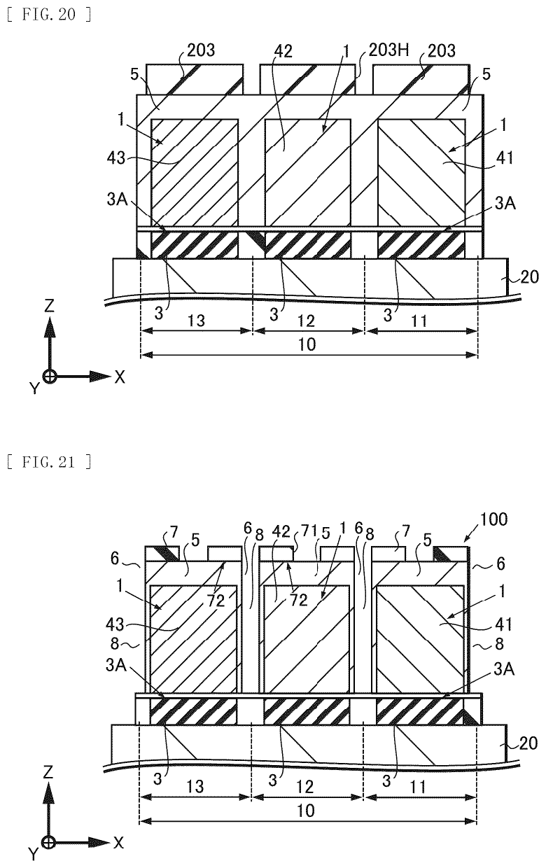

As illustrated in FIG. 19, the covering part 5 is formed across an entire surface including the first light controller 41, the second light controller 42, and the third light controller 43. The covering part 5 is embedded in the space where the pixel separator 8 is arranged.

As illustrated in FIG. 20, a mask 203 is formed on the covering part 5. In the mask 203, an opening 203H is formed in a region of the pixel separator 8. The mask 203 is formed, for example, by the photolithography technology.

As illustrated in FIG. 14 above, the covering part 5 is patterned using the mask 203. This patterning separates the covering part 5 into each of the first pixel 11, the second pixel 12, and the third pixel 13, a side surface 51 of the covering part 5 is exposed, and the first light shielding part 6 including the air gap is formed. Moreover, the covering part 5 between the first light controller 41, the second light controller 42, the third light controller 43 is removed, and the pixel separator 8 including the air gap is formed.

When the series of manufacturing processes end, the light emission device 1 and the image display apparatus 100 according to the second embodiment are completed.

### [Workings and Effects]

According to the light emission device 1 and the image display apparatus 100 according to the second embodiment, it is possible to obtain workings and effects similar to the workings and effects obtained by the light emission device 1 and the image display apparatus 100 according to the first embodiment.

Furthermore, in the light emission device 1 and the image display apparatus 100, as illustrated in FIG. 14, the first light shielding part 6 is the air gap. In addition, the pixel separator 8 is the air gap.

This makes it possible to easily realize respective structures of the first light shielding part 6 and the pixel separator 8.

### 3. Third Embodiment

A light emission device 1 and an image display apparatus 100 according to the third embodiment of the present disclosure are described.

### [Configuration of Light Emission Device 1 and Image Display Apparatus 100]

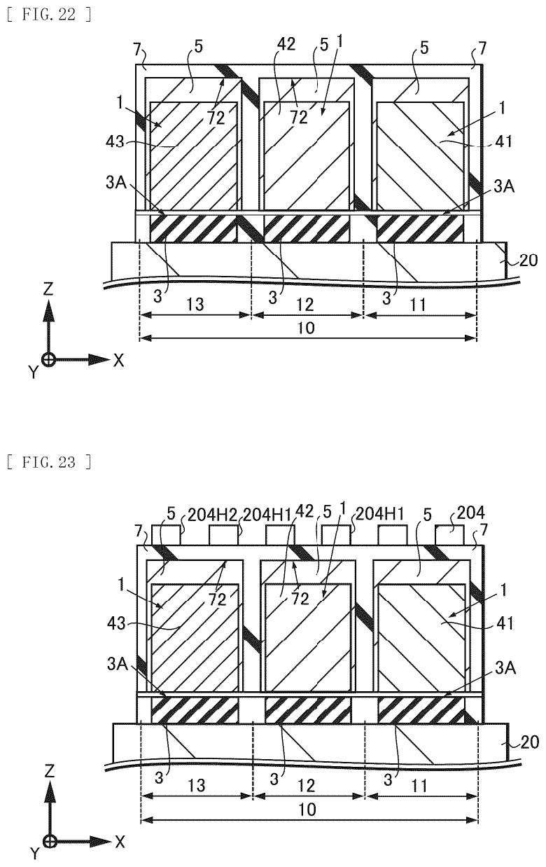

FIG. 21 illustrates an example of a vertical cross-sectional configuration of the light emission device 1 and the image display apparatus 100.

The light emission device 1 and the image display apparatus 100 according to the third embodiment are obtained by combining the light emission device 1 and the image display apparatus 100 according to the first embodiment and the light emission device 1 and the image display apparatus 100 according to the second embodiment. That is, in the light emission device 1 and the image display apparatus 100 according to the third embodiment, a first light shielding part 6 that is an air gap is disposed on a side surface of a covering part 5, and a second light shielding part 7 is disposed on the covering part 5. In addition, a pixel separator 8 is an air gap.

Components other than the above components are the same as the components of the light emission device 1 and the image display apparatus 100 according to the first embodiment or the second embodiment.

### [Method for Manufacturing Light Emission Device 1 and Image Display Apparatus 100]

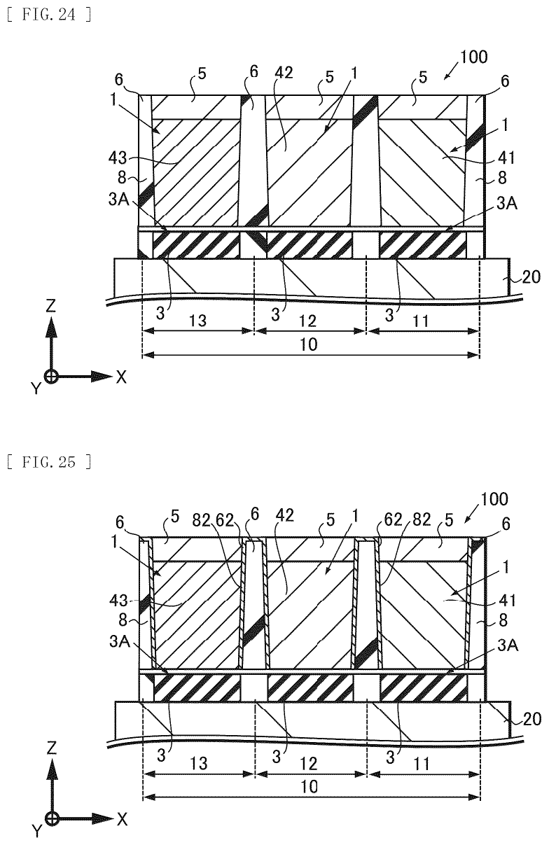

FIGS. 22 and 23 are process cross-sectional diagrams for describing a method for manufacturing the light emission device 1 and the image display apparatus 100 according to the third embodiment. The method for manufacturing the light emission device 1 and the image display apparatus 100 is as follows.

In the light emission device 1 and the image display apparatus 100 illustrated in FIG. 14 above, as illustrated in FIG. 22, the second light shielding part 7 is formed across an entire surface on the covering part 5, including a region of a color pixel 10. The second light shielding part 7 is embedded in each of the first light shielding part 6 and the pixel separator 8 formed as the air gaps.

As illustrated in FIG. 23, a mask 204 is formed on the covering part 5. In the mask 204, openings 204H1 and 204H2 are formed. The opening 204H1 is formed in a region of the first light shielding part 6 and the pixel separator 8. The opening 204H2 is formed in a region of the second light shielding part 7. The mask 204 is formed, for example, by the photolithography technology.

The first light shielding part 6 is patterned using the mask 204. This patterning removes the extra second light shielding part 7 exposed from the opening 204H1, and as illustrated in FIG. 21 above, the first light shielding part 6 and the pixel separator 8 that are the air gaps are formed. Furthermore, the extra second light shielding part 7 exposed from the opening 204H2 is removed, and an opening 71 is formed.

When the series of manufacturing processes end, the light emission device 1 and the image display apparatus 100 according to the second embodiment are completed.

### [Workings and Effects]

According to the light emission device 1 and the image display apparatus 100 according to the third embodiment, it is possible to obtain workings and effects obtained by combining the light emission device 1 and the image display apparatus 100 according to the first embodiment and the light emission device 1 and the image display apparatus 100 according to the second embodiment.

Furthermore, in the method for manufacturing the light emission device 1 and the image display apparatus 100, as illustrated in FIG. 23, each of the first light shielding part 6, the pixel separator 8, and the opening 71 is formed by the same manufacturing process. Therefore, it is possible to reduce the number of manufacturing processes.

### 4. Fourth Embodiment

A light emission device 1 and an image display apparatus 100 according to the fourth embodiment of the present disclosure are described.

### [Configuration of Light Emission Device 1 and Image Display Apparatus 100]

FIG. 24 illustrates an example of a vertical cross-sectional configuration of the light emission device 1 and the image display apparatus 100.

In the light emission device 1 and the image display apparatus 100 according to the fourth embodiment, a pixel separator 8 of the light emission device 1 and the image display apparatus 100 according to the first embodiment is extended in an arrow Z direction along a side surface of a covering part 5 to allow to form a first light shielding part 6. That is, the first light shielding part 6 includes the same material as the pixel separator 8 and is formed integrally with the pixel separator 8.

Components other than the above components are the same as the components of the light emission device 1 and the image display apparatus 100 according to the first embodiment.

### [Workings and Effects]

According to the light emission device 1 and the image display apparatus 100 according to the fourth embodiment, it is possible to obtain workings and effects similar to the workings and effects obtained by the light emission device 1 and the image display apparatus 100 according to the first embodiment.

Furthermore, in the light emission device 1 and the image display apparatus 100, the pixel separator 8 is extended along the side surface of the covering part 5 to allow to form the first light shielding part 6. This makes it possible to easily realize the first light shielding part 6 and the pixel separator 8.

### 5. Fifth Embodiment

A light emission device 1 and an image display apparatus 100 according to the fifth embodiment of the present disclosure are described.

### [Configuration of Light Emission Device 1 and Image Display Apparatus 100]

FIG. 25 illustrates an example of a vertical cross-sectional configuration of the light emission device 1 and the image display apparatus 100.

In the light emission device 1 and the image display apparatus 100 according to the fifth embodiment, a second reflection region 62 is disposed at least on a side of a covering part 5 of a first light shielding part 6 in the light emission device 1 and the image display apparatus 100 according to the fourth embodiment. The second reflection region 62 reflects light. The second reflection region 62 includes a material with a high reflectance, for example, Al or the like, for example, similarly to a first reflection region 72.

Moreover, in the light emission device 1 and the image display apparatus 100, a third reflection region 82 is disposed at least on a side of a first light controller 41, a second light controller 42, or a third light controller 43 of a pixel separator 8. The third reflection region 82 reflects light, similarly to the second reflection region 62. Here, the third reflection region 82 includes the same material as the second reflection region 62 and is formed integrally with the second reflection region 62.

Components other than the above components are the same as the components of the light emission device 1 and the image display apparatus 100 according to the first embodiment.

### [Workings and Effects]

According to the light emission device 1 and the image display apparatus 100 according to the fifth embodiment, it is possible to obtain workings and effects similar to the workings and effects obtained by the light emission device 1 and the image display apparatus 100 according to the first embodiment.

Furthermore, the light emission device 1 and the image display apparatus 100 include the second reflection region 62 at least on the side of the covering part 5 of the first light shielding part 6.

Because this makes it possible to efficiently emit light emitted from a light emission surface 3A of a light emitting element 3, reflected by the second reflection region 62, and controlled by the first light controller 41, it is possible to realize higher luminance in an emission direction. For light controlled by each of the second light controller 42 and the third light controller 43, it is possible to obtain similar workings and effects.

Moreover, the light emission device 1 and the image display apparatus 100 include the third reflection region 82 at least on the side of the first light controller 41, the second light controller 42, or the third light controller 43 of the pixel separator 8.

Because this makes it possible to efficiently emit the light emitted from the light emission surface 3A of the light emitting element 3, reflected by the third reflection region 82, and controlled by the first light controller 41, it is possible to realize higher luminance in the emission direction. For the light controlled by each of the second light controller 42 and the third light controller 43, it is possible to obtain similar workings and effects.

### 6. Sixth Embodiment

A light emission device 1 and an image display apparatus 100 according to the sixth embodiment of the present disclosure are described.

### [Configuration of Light Emission Device 1 and Image Display Apparatus 100]

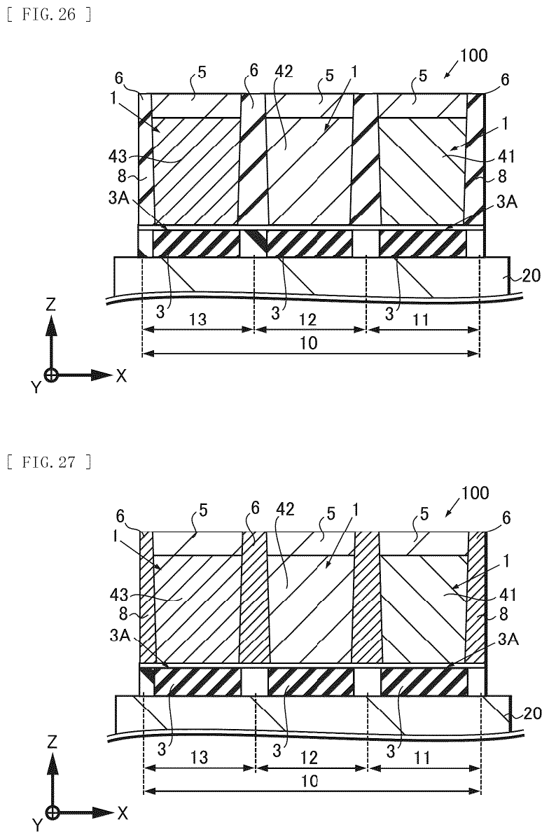

FIG. 26 illustrates an example of a vertical cross-sectional configuration of the light emission device 1 and the image display apparatus 100.

In the light emission device 1 and the image display apparatus 100 according to the sixth embodiment, at least a portion of a first light shielding part 6 includes a material having a lower refractive index than a covering part 5 in the light emission device 1 and the image display apparatus 100 according to the fourth embodiment. Here, the entire first light shielding part 6 includes the material having the low refractive index.

For the first light shielding part 6, for example, it is possible to use a fluorine resin, magnesium fluoride (MgF), calcium fluoride (CaF), or the like.

Furthermore, at least a portion of a pixel separator 8 includes a material having a lower refractive index than a first light controller 41, a second light controller 42, or a third light controller 43. Here, the entire pixel separator 8 includes the material having the low refractive index, similarly to the first light shielding part 6.

Components other than the above components are the same as the components of the light emission device 1 and the image display apparatus 100 according to the fourth embodiment.

### [Workings and Effects]

According to the light emission device 1 and the image display apparatus 100 according to the sixth embodiment, it is possible to obtain workings and effects similar to the workings and effects obtained by the light emission device 1 and the image display apparatus 100 according to the fourth embodiment.

Furthermore, in the light emission device 1 and the image display apparatus 100, the first light shielding part 6 includes the material having the low refractive index. Similarly, the pixel separator 8 includes the material having the low refractive index.

This makes it possible to effectively suppress or prevent leaked light between the adjacent covering parts 5 and between the adjacent pixel separators 8.

### 7. Seventh Embodiment

A light emission device 1 and an image display apparatus 100 according to the seventh embodiment of the present disclosure are described.

### [Configuration of Light Emission Device 1 and Image Display Apparatus 100]

FIG. 27 illustrates an example of a vertical cross-sectional configuration of the light emission device 1 and the image display apparatus 100.

In the light emission device 1 and the image display apparatus 100 according to the seventh embodiment, at least a portion of a first light shielding part 6 includes a material having a higher light absorptivity than a covering part 5 in the light emission device 1 and the image display apparatus 100 according to the fourth embodiment. Here, the entire first light shielding part 6 includes the material having the high light absorptivity.

For the first light shielding part 6, it is possible to use, for example, a resin, a black (for example, carbon black or the like), or the like, having high light absorbability.

Furthermore, at least a portion of a pixel separator 8 includes a material having a higher light absorptivity than a first light controller 41, a second light controller 42, or a third light controller 43. Here, the entire pixel separator 8 includes the material having the high light absorptivity, similarly to the first light shielding part 6.

Components other than the above components are the same as the components of the light emission device 1 and the image display apparatus 100 according to the fourth embodiment.

### [Workings and Effects]

According to the light emission device 1 and the image display apparatus 100 according to the seventh embodiment, it is possible to obtain workings and effects similar to the workings and effects obtained by the light emission device 1 and the image display apparatus 100 according to the fourth embodiment.

Furthermore, in the light emission device 1 and the image display apparatus 100, the first light shielding part 6 includes the material having the high light absorptivity. Similarly, the pixel separator 8 includes the material having the high light absorptivity.

This makes it possible to effectively suppress or prevent leaked light between the adjacent covering parts 5 and between the adjacent pixel separators 8.

### 8. Eighth Embodiment

A light emission device 1 and an image display apparatus 100 according to the eighth embodiment of the present disclosure are described.

### [Configuration of Light Emission Device 1 and Image Display Apparatus 100]

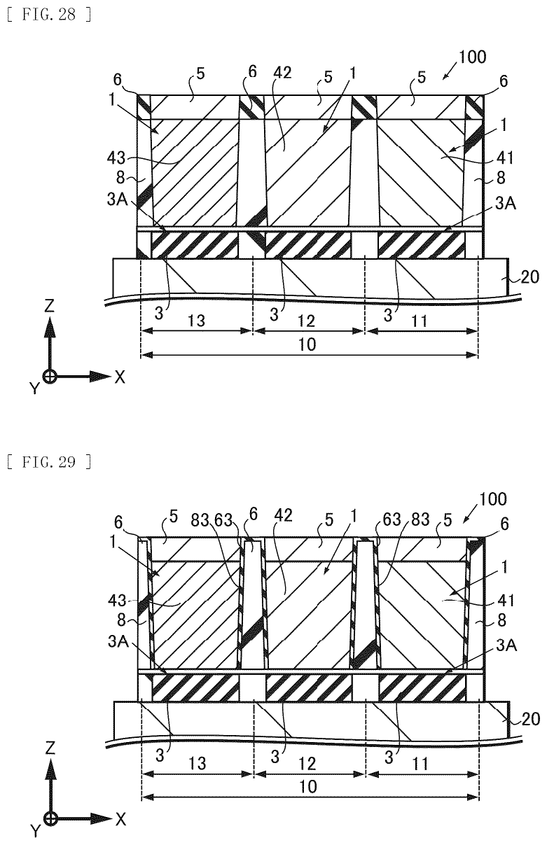

FIG. 28 illustrates an example of a vertical cross-sectional configuration of the light emission device 1 and the image display apparatus 100.

In the light emission device 1 and the image display apparatus 100 according to the eighth embodiment, a first light shielding part 6 includes a hardly-removable material of which a process speed is lower than that of a covering part 5, in the light emission device 1 and the image display apparatus 100 according to the fourth embodiment. Here, the entire first light shielding part 6 includes the hardly-removable material.

In a case where the covering part 5 includes, for example, a resin, the first light shielding part 6 includes a metal material that satisfies the following inequality expression.

process speed of covering part 5<process speed of first light shielding part 6

Here, the process is, for example, a process for polishing a surface of the covering part 5 and a surface of the first light shielding part 6, in the same process. Specifically, this is a polishing process performed by using loose grains such as alumina or silica and abrasive cloth including urethane or the like in combination. As the metal material of the first light shielding part 6, it is possible to practically use Cu, Al, tungsten (W), Ti, Ag, Au, nickel (Ni), or the like.

Components other than the above components are the same as the components of the light emission device 1 and the image display apparatus 100 according to the fourth embodiment.

### [Workings and Effects]

According to the light emission device 1 and the image display apparatus 100 according to the eighth embodiment, it is possible to obtain workings and effects similar to the workings and effects obtained by the light emission device 1 and the image display apparatus 100 according to the fourth embodiment.

Furthermore, in the light emission device 1 and the image display apparatus 100, the first light shielding part 6 includes the hardly-removable material.

This makes it possible to secure a selection ratio of the process speed for each of the covering part 5 and the first light shielding part 6, and for example, it is possible to process the covering part 5 as adjusting a thickness of the covering part 5 with reference to a thickness of the first light shielding part 6. Therefore, it is possible to easily control the thickness of the covering part 5.

### 9. Ninth Embodiment

A light emission device 1 and an image display apparatus 100 according the ninth embodiment of the present disclosure are described.

### [Configuration of Light Emission Device 1 and Image Display Apparatus 100]

FIG. 29 illustrates an example of a vertical cross-sectional configuration of the light emission device 1 and the image display apparatus 100.

In the light emission device 1 and the image display apparatus 100 according to the ninth embodiment, a hardly-removable region 63 of which a process speed is lower than that of a covering part 5 is formed on a top surface and a side surface of a first light shielding part 6, in the light emission device 1 and the image display apparatus 100 according to the fourth embodiment. The hardly-removable region 63 includes the hardly-removable material described with reference to the light emission device 1 and the image display apparatus 100 according to the eighth embodiment.

Moreover, a hardly-removable region 83 similar to the hardly-removable region 63 is formed on a side surface of a pixel separator 8.

Components other than the above components are the same as the components of the light emission device 1 and the image display apparatus 100 according to the fourth embodiment.

### [Method for Manufacturing Light Emission Device 1 and Image Display Apparatus 100]

FIGS. 30 to 37 are process cross-sectional diagrams for describing a method for manufacturing the light emission device 1 and the image display apparatus 100 according to the ninth embodiment. The method for manufacturing the light emission device 1 and the image display apparatus 100 is as follows.

First, as illustrated in FIG. 30, a pixel separation film 85 is formed on a light emitting element 3 in a region of each of a first pixel 11, a second pixel 12, and a third pixel 13 of a color pixel 10.

As illustrated in FIG. 31, a mask 205 is formed on the pixel separation film 85. In the mask 205, an opening 205H is formed in a region of each of a first light controller 41, a second light controller 42, and a third light controller 43. The mask 205 is formed, for example, by the photolithography technology.

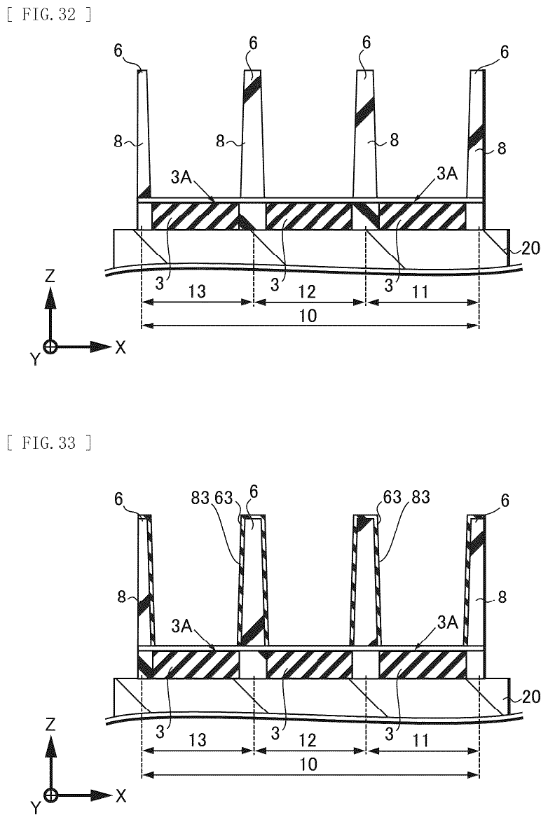

As illustrated in FIG. 32, the pixel separation film 85 is patterned using the mask 205. The pixel separator 8 and the first light shielding part 6 include a portion where the pixel separation film 85 is not removed.

As illustrated in FIG. 33, the hardly-removable region 63 is formed on the top surface and the side surface of the first light shielding part 6, and the hardly-removable region 83 is formed on the side surface of the pixel separator 8.

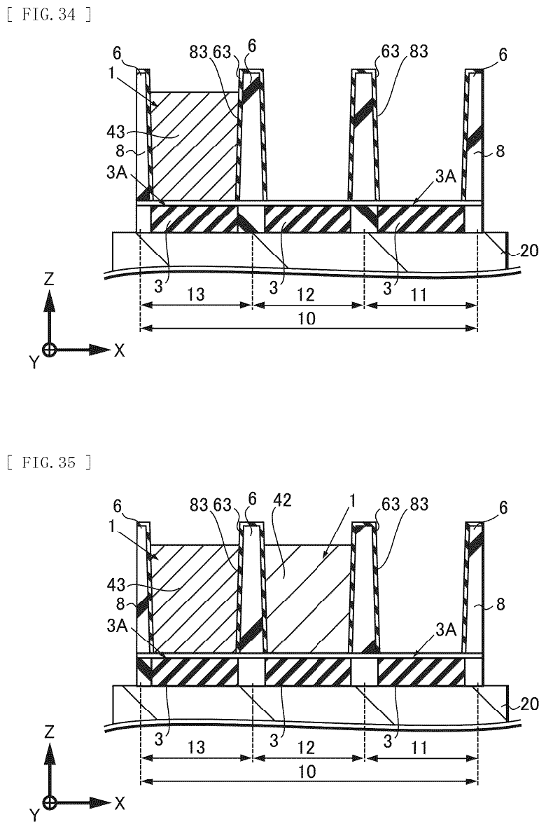

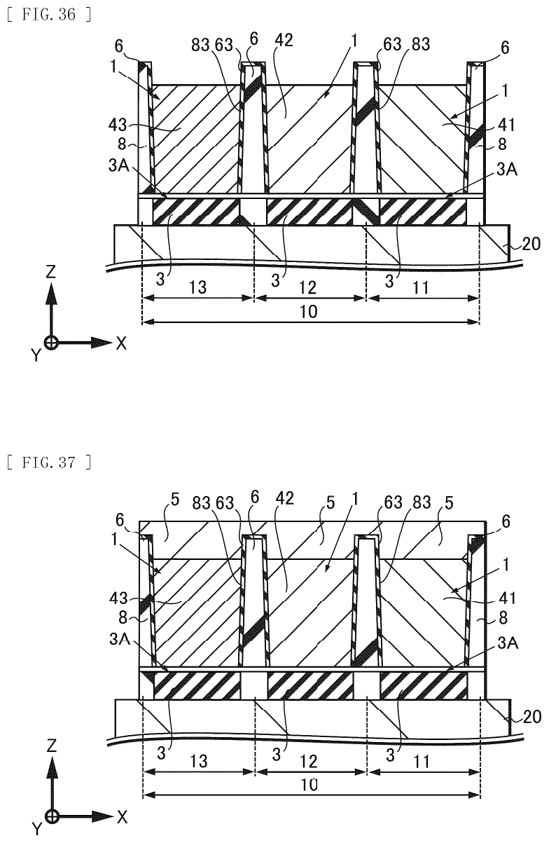

As illustrated in FIG. 34, the third light controller 43 is formed on the light emitting element 3 to be the third pixel 13. Subsequently, as illustrated in FIG. 35, the second light controller 42 is formed on the light emitting element 3 to be the second pixel 12. Then, as illustrated in FIG. 36, the first light controller 41 is formed on the light emitting element 3 to be the first pixel 11.

Here, each of the first light controller 41, the second light controller 42, and the third light controller 43 is formed in a region surrounded by the pixel separator 8 and the first light shielding part 6.

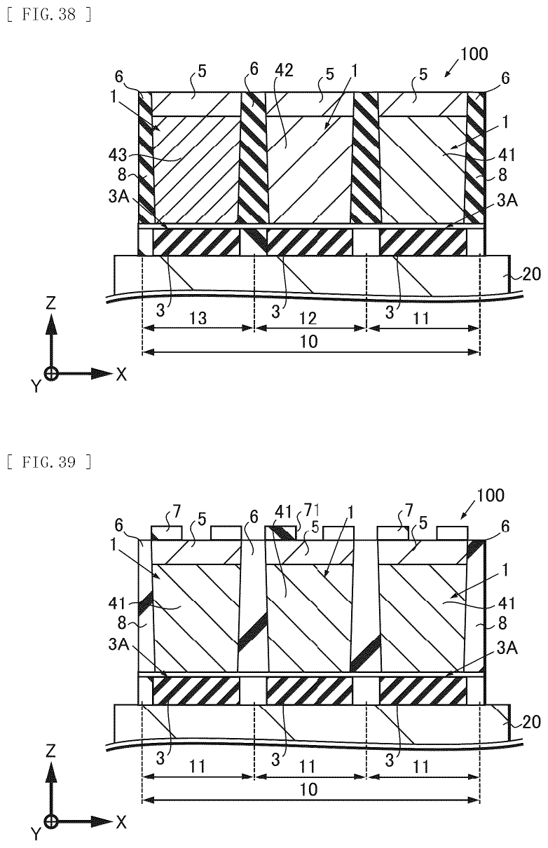

As illustrated in FIG. 37, the covering part 5 is formed across the entire surface including the first light controller 41, the second light controller 42, and the third light controller 43. The covering part 5 is formed to be thicker than heights of the first covering part 5 and the hardly-removable region 63.

As illustrated in FIG. 29 above, the thickness of the covering part 5 is controlled. Here, the covering part 5 is polished by a polishing method and is formed to have the same thickness as the height of the hardly-removable region 63 on the top surface of the first light shielding part 6.

When the series of manufacturing processes end, the light emission device 1 and the image display apparatus 100 according to the ninth embodiment are completed.

### [Workings and Effects]

According to the light emission device 1 and the image display apparatus 100 according to the ninth embodiment, it is possible to obtain workings and effects similar to the workings and effects obtained by the light emission device 1 and the image display apparatus 100 according to the eighth embodiment.

Furthermore, in the light emission device 1 and the image display apparatus 100, the hardly-removable region 63 is formed on the first light shielding part 6.

This makes it possible to secure a process selection ratio for each of the covering part 5 and the first light shielding part 6, and for example, it is possible to process the covering part 5 as adjusting the thickness of the covering part 5 with reference to the thickness of the first light shielding part 6. Therefore, it is possible to easily control the thickness of the covering part 5.

### 10. Tenth Embodiment

A light emission device 1 and an image display apparatus 100 according to the tenth embodiment of the present disclosure are described.

### [Configuration of Light Emission Device 1 and Image Display Apparatus 100]

FIG. 38 illustrates an example of a vertical cross-sectional configuration of the light emission device 1 and the image display apparatus 100.

In the light emission device 1 and the image display apparatus 100 according to the tenth embodiment, a pixel separator 8 includes a hardly-removable material, in the light emission device 1 and the image display apparatus 100 according to the eighth embodiment. Here, because a first light shielding part 6 includes the hardly-removable material, the first light shielding part 6 and the pixel separator 8 include the hardly-removable material and are integrally formed.

Components other than the above components are the same as the components of the light emission device 1 and the image display apparatus 100 according to the eighth embodiment.

### [Workings and Effects]

According to the light emission device 1 and the image display apparatus 100 according to the tenth embodiment, it is possible to obtain workings and effects similar to the workings and effects obtained by the light emission device 1 and the image display apparatus 100 according to the eighth embodiment.

Furthermore, in the light emission device 1 and the image display apparatus 100, because the first light shielding part 6 and the pixel separator 8 include the hardly-removable material, it is possible to simply realize the first light shielding part 6 and the pixel separator 8 that allow to control the thickness of the covering part 5.

### 11. Eleventh Embodiment

A light emission device 1 and an image display apparatus 100 according to the eleventh embodiment of the present disclosure are described.

### [Configuration of Light Emission Device 1 and Image Display Apparatus 100]

FIG. 39 illustrates an example of a vertical cross-sectional configuration of the light emission device 1 and the image display apparatus 100.

In the light emission device 1 and the image display apparatus 100 according to the eleventh embodiment, a color pixel 10 is constructed by the same first pixels 11 in the light emission device 1 and the image display apparatus 100 according to the first embodiment or the light emission device 1 and the image display apparatus 100 according to the fourth embodiment. That is, the color pixel 10 is constructed by arranging the plurality of first pixels 11 including a first light controller 41 that emits red light.

Note that the color pixel 10 may be constructed by the same second pixels 12 or the same third pixels 13.

Components other than the above components are the same as the components of the light emission device 1 and the image display apparatus 100 according to the first embodiment and the fourth embodiment.

### [Workings and Effects]

According to the light emission device 1 and the image display apparatus 100 according to the eleventh embodiment, it is possible to obtain workings and effects obtained by combining the light emission device 1 and the image display apparatus 100 according to the first embodiment and the light emission device 1 and the image display apparatus 100 according to the fourth embodiment.

### 12. Twelfth Embodiment

A light emission device 1 and an image display apparatus 100 according to the twelfth embodiment of the present disclosure are described.

### [Configuration of Light Emission Device 1 and Image Display Apparatus 100]

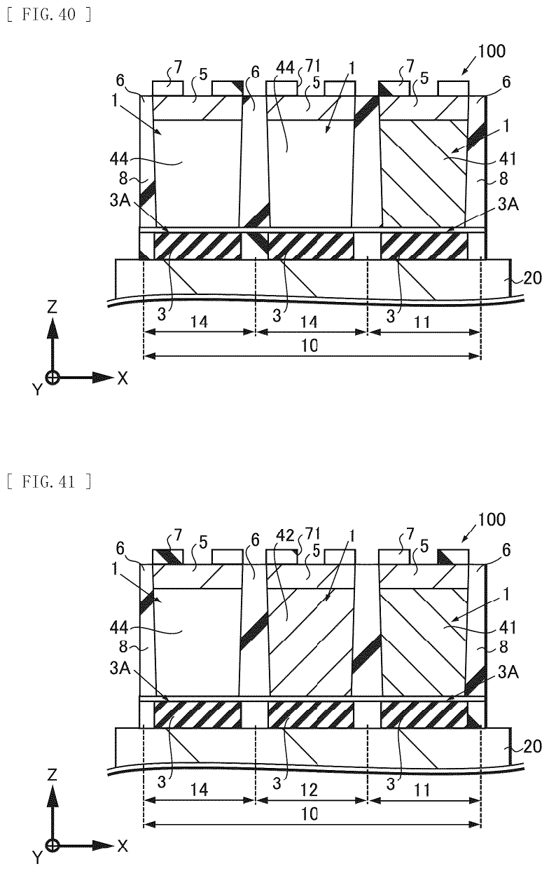

FIG. 40 illustrates an example of a vertical cross-sectional configuration of the light emission device 1 and the image display apparatus 100.

In the light emission device 1 and the image display apparatus 100 according to the twelfth embodiment, a color pixel 10 is constructed by a single first pixel 11 and two fourth pixels 14 in the light emission device 1 and the image display apparatus 100 according to the eleventh embodiment.

The fourth pixel 14 includes a light emitting element 3 and a transparent part 44 on the light emitting element 3. The transparent part 44 includes, for example, a transparent resin and emits, for example, blue light emitted from a light emission surface 3A without performing wavelength conversion.

Components other than the above components are the same as the components of the light emission device 1 and the image display apparatus 100 according to the eleventh embodiment.

### [Workings and Effects]

According to the light emission device 1 and the image display apparatus 100 according to the twelfth embodiment, it is possible to obtain workings and effects similar to the workings and effects obtained by the light emission device 1 and the image display apparatus 100 according to the eleventh embodiment.

### 13. Thirteenth Embodiment

A light emission device 1 and an image display apparatus 100 according to the thirteenth embodiment of the present disclosure are described.

### [Configuration of Light Emission Device 1 and Image Display Apparatus 100]

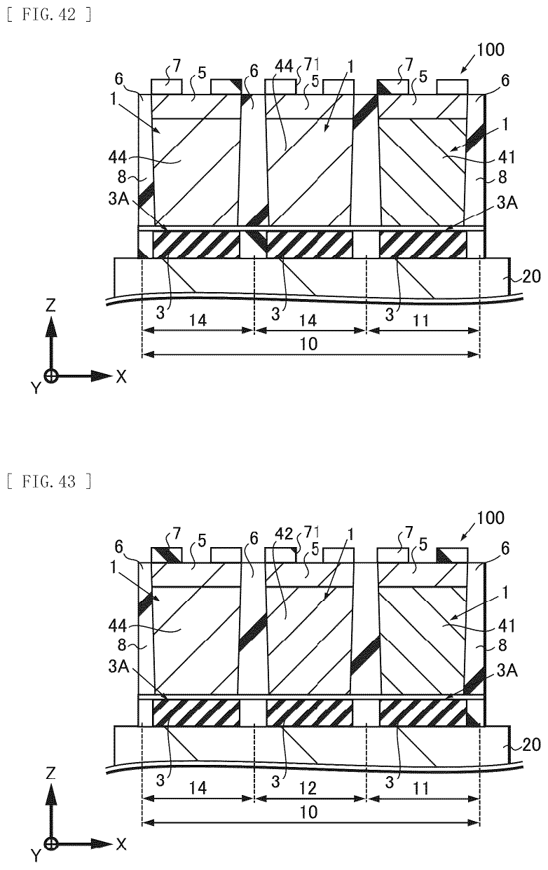

FIG. 41 illustrates an example of a vertical cross-sectional configuration of the light emission device 1 and the image display apparatus 100.

In the light emission device 1 and the image display apparatus 100 according to the thirteenth embodiment, a color pixel 10 is constructed by a single first pixel 11, a single second pixel 12, and a single fourth pixel 14 in the light emission device 1 and the image display apparatus 100 according to the twelfth embodiment.

The second pixel 12 includes a second light controller 42 and emits green light.

Components other than the above components are the same as the components of the light emission device 1 and the image display apparatus 100 according to the twelfth embodiment.

### [Workings and Effects]

According to the light emission device 1 and the image display apparatus 100 according to the thirteenth embodiment, it is possible to obtain workings and effects similar to the workings and effects obtained by the light emission device 1 and the image display apparatus 100 according to the twelfth embodiment.

### 14. Fourteenth Embodiment

A light emission device 1 and an image display apparatus 100 according to the fourteenth embodiment of the present disclosure are described.

### [Configuration of Light Emission Device 1 and Image Display Apparatus 100]

FIGS. 42 and 43 illustrate an example of a vertical cross-sectional configuration of the light emission device 1 and the image display apparatus 100.

As illustrated in FIG. 42, in the light emission device 1 and the image display apparatus 100 according to the fourteenth embodiment, a transparent part 44 of a fourth pixel 14 includes the same material as a covering part 5, in the light emission device 1 and the image display apparatus 100 according to the twelfth embodiment. For example, each of the transparent part 44 and the covering part 5 includes a resin. Here, a color pixel 10 is constructed by a single first pixel 11 and two fourth pixels 14.

Furthermore, as illustrated in FIG. 43, in the light emission device 1 and the image display apparatus 100 according to the fourteenth embodiment, the transparent part 44 of the fourth pixel 14 includes the same material as the covering part 5, in the light emission device 1 and the image display apparatus 100 according to the thirteenth embodiment. Here, the color pixel 10 is constructed by the single first pixel 11, a single second pixel 12, and the single fourth pixel 14.

Components other than the above components are the same as the components of the light emission device 1 and the image display apparatus 100 according to the twelfth embodiment or the thirteenth embodiment.

### [Workings and Effects]

According to the light emission device 1 and the image display apparatus 100 according to the fourteenth embodiment, it is possible to obtain workings and effects similar to the workings and effects obtained by the light emission device 1 and the image display apparatus 100 according to the twelfth embodiment. Furthermore, according to the light emission device 1 and the image display apparatus 100 according to the fourteenth embodiment, it is possible to obtain workings and effects similar to the workings and effects obtained by the light emission device 1 and the image display apparatus 100 according to the thirteenth embodiment.

### 15. Fifteenth Embodiment

A light emission device 1 and an image display apparatus 100 according to the fifteenth embodiment of the present disclosure are described.

### [Configuration of Light Emission Device 1 and Image Display Apparatus 100]

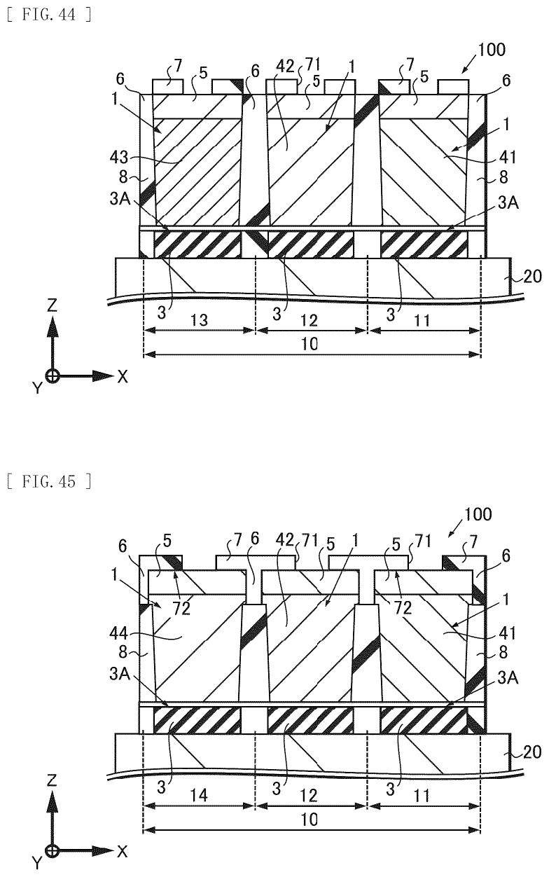

FIG. 44 illustrates an example of a vertical cross-sectional configuration of the light emission device 1 and the image display apparatus 100.

In the light emission device 1 and the image display apparatus 100 according to the fifteenth embodiment, a color pixel 10 is constructed by a single first pixel 11, a single second pixel 12, and a single third pixel 13, in the light emission device 1 and the image display apparatus 100 according to the fourteenth embodiment.

Components other than the above components are the same as the components of the light emission device 1 and the image display apparatus 100 according to the fourteenth embodiment.

### [Workings and Effects]

According to the light emission device 1 and the image display apparatus 100 according to the fifteenth embodiment, it is possible to obtain workings and effects similar to the workings and effects obtained by the light emission device 1 and the image display apparatus 100 according to the fourteenth embodiment.

### 16. Sixteenth Embodiment

A light emission device 1 and an image display apparatus 100 according to the sixteenth embodiment of the present disclosure are described.

### [Configuration of Light Emission Device 1 and Image Display Apparatus 100]

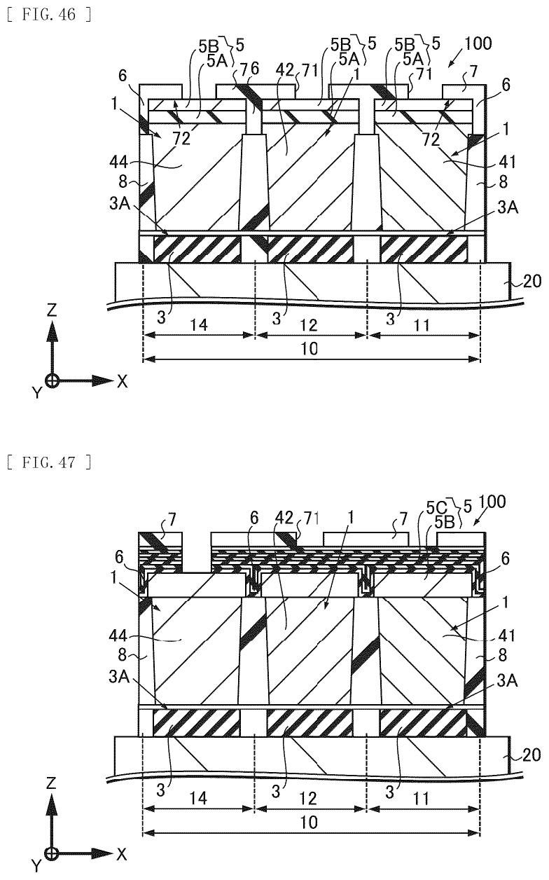

FIG. 45 illustrates an example of a vertical cross-sectional configuration of the light emission device 1 and the image display apparatus 100.

As illustrated in FIG. 45, in the light emission device 1 and the image display apparatus 100 according to the sixteenth embodiment, a covering part 5 includes an inorganic material, in the light emission device 1 and the image display apparatus 100 (refer to FIG. 43) according to the fourteenth embodiment. As the inorganic material, for example, it is possible to use Al₂O₃, SiO, silicon oxynitride (SiON), or the like. Here, because a color pixel 10 includes a fourth pixel 14, the fourth pixel 14 has a structure in which a resin of a transparent part 44 and the inorganic material of the covering part 5 are stacked.

Components other than the above components are the same as the components of the light emission device 1 and the image display apparatus 100 according to the fourteenth embodiment.

### [Workings and Effects]

According to the light emission device 1 and the image display apparatus 100 according to the sixteenth embodiment, it is possible to obtain workings and effects similar to the workings and effects obtained by the light emission device 1 and the image display apparatus 100 according to the fourteenth embodiment.

### 17. Seventeenth Embodiment

A light emission device 1 and an image display apparatus 100 according to the seventeenth embodiment of the present disclosure are described.

### [Configuration of Light Emission Device 1 and Image Display Apparatus 100]

FIG. 46 illustrates an example of a vertical cross-sectional configuration of the light emission device 1 and the image display apparatus 100.

As illustrated in FIG. 46, in the light emission device 1 and the image display apparatus 100 according to the seventeenth embodiment, a color pixel 10 is constructed by a first pixel 11, a second pixel 12, and a fourth pixel 14, similarly to the light emission device 1 and the image display apparatus 100 according to the fourteenth embodiment. A covering part 5 of the fourth pixel 14 includes a single layer structure of a resin.

On the other hand, a covering part 5 of each of the first pixel 11, the second pixel 12, and the fourth pixel 14 includes a composite structure including a first covering part 5A and a second covering part 5B stacked on the first covering part 5A. The first covering part 5A includes, for example, an inorganic material. The second covering part 5B includes, for example, a different type of an inorganic material or a resin from the first covering part 5A.

Components other than the above components are the same as the components of the light emission device 1 and the image display apparatus 100 according to the fourteenth embodiment.

### [Workings and Effects]

According to the light emission device 1 and the image display apparatus 100 according to the seventeenth embodiment, it is possible to obtain workings and effects similar to the workings and effects obtained by the light emission device 1 and the image display apparatus 100 according to the fourteenth embodiment.

### 18. Eighteenth Embodiment

A light emission device 1 and an image display apparatus 100 according to the eighteenth embodiment of the present disclosure are described.

### [Configuration of Light Emission Device 1 and Image Display Apparatus 100]

FIG. 47 illustrates an example of a vertical cross-sectional configuration of the light emission device 1 and the image display apparatus 100.

As illustrated in FIG. 47, in the light emission device 1 and the image display apparatus 100 according to the eighteenth embodiment, a color pixel 10 is constructed by a first pixel 11, a second pixel 12, and a fourth pixel 14, similarly to the light emission device 1 and the image display apparatus 100 according to the seventeenth embodiment.

On the other hand, a covering part 5 of each of the first pixel 11, the second pixel 12, and the fourth pixel 14 includes a composite structure including a second covering part 5B and a third covering part 5C stacked on the second covering part 5B. The second covering part 5B includes, for example, a resin as described above. The third covering part 5C includes, for example, a dielectric multi-layer film. The dielectric multi-layer film constructs a distributed bragg reflector (DBR: Distributed Bragg Reflector), by stacking at least two or more types of dielectric bodies having different refractive indexes, that transmits only light with a specific wavelength. The dielectric multi-layer film is formed by alternately stacking SiO and niobium oxide (NbO) a plurality of times, for example. Furthermore, the dielectric multi-layer film may be formed by alternately stacking SiO and titanium oxide (TiO₂) or alternately stacking SiO and SiN a plurality of times.

Furthermore, for the third covering part 5C, the dielectric multi-layer film may be changed to a semiconductor multi-layer film. For example, the semiconductor multi-layer film is formed by stacking a plurality of semiconductors having at least two or more types of refractive indexes selected from among InP, AlₓGa_{y}In_{1-x-y}As (0≤x, y≤1), and InₓGa₁₋ₓAs_{1-y}P_{y} (0≤x, y≤1).

Furthermore, in the eighteenth embodiment, the third covering part 5C is extended along a side surface of the covering part 5, and the third covering part 5C forms a first light shielding part 6.

Components other than the above components are the same as the components of the light emission device 1 and the image display apparatus 100 according to the seventeenth embodiment.

### [Workings and Effects]

According to the light emission device 1 and the image display apparatus 100 according to the eighteenth embodiment, it is possible to obtain workings and effects similar to the workings and effects obtained by the light emission device 1 and the image display apparatus 100 according to the seventeenth embodiment.

### 19. Nineteenth Embodiment

A light emission device 1 and an image display apparatus 100 according to the nineteenth embodiment of the present disclosure are described.

### [Configuration of Light Emission Device 1 and Image Display Apparatus 100]

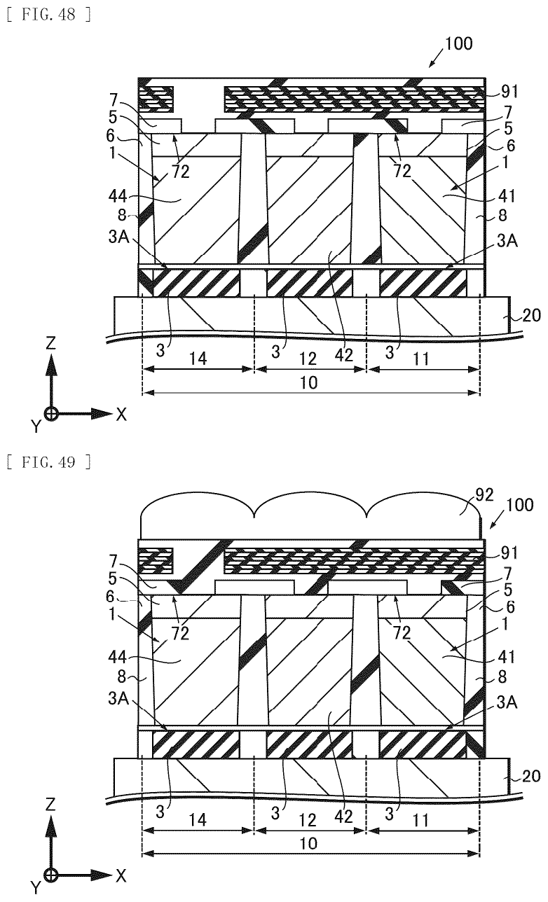

FIG. 48 illustrates an example of a vertical cross-sectional configuration of the light emission device 1 and the image display apparatus 100.

As illustrated in FIG. 48, in the light emission device 1 and the image display apparatus 100 according to the nineteenth embodiment, a dielectric multi-layer film 91 is disposed on a second light shielding part 7, in the light emission device 1 and the image display apparatus 100 according to the fourteenth embodiment. The dielectric multi-layer film is a DBR, similarly to the third covering part 5C of the light emission device 1 and the image display apparatus 100 according to the eighteenth embodiment.

Components other than the above components are the same as the components of the light emission device 1 and the image display apparatus 100 according to the fourteenth embodiment.

### [Workings and Effects]

According to the light emission device 1 and the image display apparatus 100 according to the nineteenth embodiment, it is possible to obtain workings and effects similar to the workings and effects obtained by the light emission device 1 and the image display apparatus 100 according to the fourteenth embodiment.

### 20. Twentieth Embodiment

A light emission device 1 and an image display apparatus 100 according to the twentieth embodiment of the present disclosure are described.

### [Configuration of Light Emission Device 1 and Image Display Apparatus 100]

FIG. 49 illustrates an example of a vertical cross-sectional configuration of the light emission device 1 and the image display apparatus 100.

As illustrated in FIG. 49, in the light emission device 1 and the image display apparatus 100 according to the twentieth embodiment, an optical path controller 92 is further disposed on a dielectric multi-layer film 91, in the light emission device 1 and the image display apparatus 100 according to the nineteenth embodiment. The optical path controller 92 controls an optical path of light emitted from each of a first pixel 11, a second pixel 12, and a third pixel 13. Here, control for narrowing the optical path is performed by the optical path controller 92. The optical path controller 92 includes, for example, a microlens.

Components other than the above components are the same as the components of the light emission device 1 and the image display apparatus 100 according to the nineteenth embodiment.

### [Workings and Effects]

According to the light emission device 1 and the image display apparatus 100 according to the twentieth embodiment, it is possible to obtain workings and effects similar to the workings and effects obtained by the light emission device 1 and the image display apparatus 100 according to the nineteenth embodiment.

### 21. Twenty-First Embodiment

A light emission device 1 and an image display apparatus 100 according to the twenty-first embodiment of the present disclosure are described.

### [Configuration of Light Emission Device 1 and Image Display Apparatus 100]

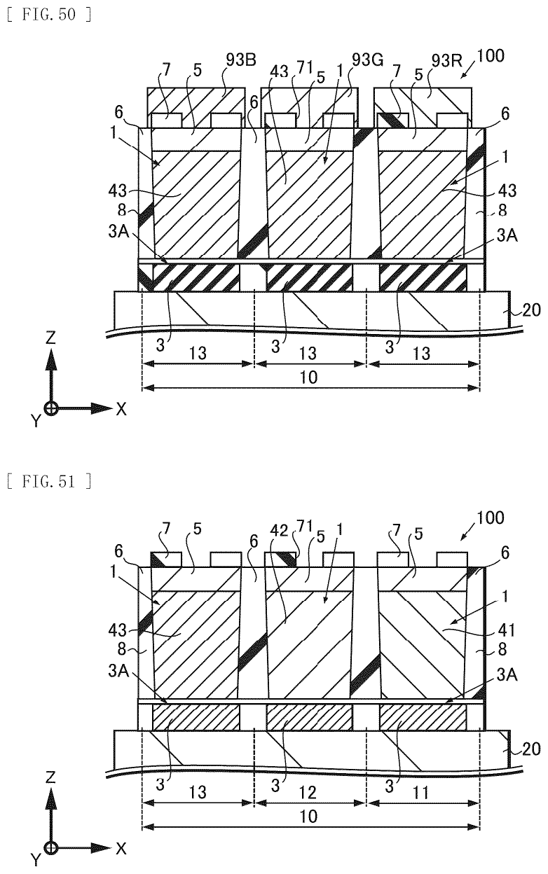

FIG. 50 illustrates an example of a vertical cross-sectional configuration of the light emission device 1 and the image display apparatus 100.

As illustrated in FIG. 50, in the light emission device 1 and the image display apparatus 100 according to the twenty-first embodiment, a color pixel 10 is constructed by three third pixels 13 in the light emission device 1 and the image display apparatus 100 according to any one of the first embodiment to the fifteenth embodiment. That is, the third pixel 13 includes a third light controller 43 that emits blue light. Furthermore, the third light controller 43 may be replaced with a color conversion material in which a red color conversion material and a green color conversion material are mixed.

Then, each of color filters 93R, 93G, and 93B is disposed on a second light shielding part 7 of the third pixel 13. The color filter 93R performs modulation into red light. The color filter 93G performs modulation into green light. The color filter 93B performs modulation into blue light.

Components other than the above components are the same as the components of the light emission device 1 and the image display apparatus 100 according to any one of the first embodiment to the fifteenth embodiment.

### [Workings and Effects]

According to the light emission device 1 and the image display apparatus 100 according to the twenty-first embodiment, it is possible to obtain workings and effects similar to the workings and effects obtained by the light emission device 1 and the image display apparatus 100 according to any one of the first embodiment to the fifteenth embodiment.

### 22. Twenty-Second Embodiment

A light emission device 1 and an image display apparatus 100 according to the twenty-second embodiment of the present disclosure are described.

### [Configuration of Light Emission Device 1 and Image Display Apparatus 100]

FIG. 51 illustrates an example of a vertical cross-sectional configuration of the light emission device 1 and the image display apparatus 100.

As illustrated in FIG. 51, in the light emission device 1 and the image display apparatus 100 according to the twenty-second embodiment, an organic light emitting diode (OLED: Organic Light Emitting Diode) is used for a light emitting element 3, in the light emission device 1 and the image display apparatus 100 according to any one of the first embodiment to the twenty-first embodiment.

Components other than the above components are the same as the components of the light emission device 1 and the image display apparatus 100 according to any one of the first embodiment to the twenty-first embodiment.

### [Workings and Effects]

According to the light emission device 1 and the image display apparatus 100 according to the twenty-second embodiment, it is possible to obtain workings and effects similar to the workings and effects obtained by the light emission device 1 and the image display apparatus 100 according to any one of the first embodiment to the twenty-first embodiment.

### 23. Twenty-Third Embodiment

A light emission device 1 and an image display apparatus 100 according to the twenty-third embodiment of the present disclosure are described.

### [Configuration of Light Emission Device 1 and Image Display Apparatus 100]

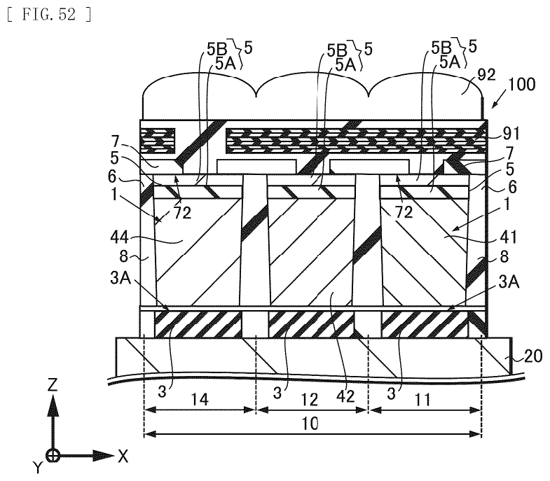

FIG. 52 illustrates an example of a vertical cross-sectional configuration of the light emission device 1 and the image display apparatus 100.

As illustrated in FIG. 52, in the light emission device 1 and the image display apparatus 100 according to the twenty-third embodiment, the light emission device 1 and the image display apparatus 100 according to the seventeenth embodiment and the light emission device 1 and the image display apparatus 100 according to the twentieth embodiment are combined.

Components other than the above components are the same as the components of the light emission device 1 and the image display apparatus 100 according to the seventeenth embodiment and the twentieth embodiment.

### [Workings and Effects]

According to the light emission device 1 and the image display apparatus 100 according to the twenty-third embodiment, it is possible to obtain workings and effects obtained by combining the light emission device 1 and the image display apparatus 100 according to the seventeenth embodiment and the light emission device 1 and the image display apparatus 100 according to the twentieth embodiment.

### 24. Other Embodiments

The present technology is not limited to the above embodiments, and it is possible to make various modifications without departing from the gist thereof.

For example, in the present technology, it is possible to combine the two or more of the plurality of above embodiments, in addition to those that have been already described above.

In the present disclosure, the light emission device includes the light emitting element and the first light controller. The light emitting element has the light emission surface. The first light controller is formed on the light emission surface and controls at least one of the wavelength of light, the diffusion of light, or the direction of light.

Then, the light emission device further includes the covering part and the first light shielding part.

The covering part is formed on the opposite side to the light emission surface of the first light controller and covers and protects the first light controller. This makes it possible to effectively suppress or prevent the damage on the first light controller by the covering part.

On the other hand, the first light shielding part is formed on the side surface of the covering part and shields light. This makes it possible to effectively suppress or prevent the leaked light.

Therefore, it is possible for the light emission device to effectively suppress or prevent the crosstalk and to improve the wavelength conversion characteristics.

Moreover, the image display apparatus including the plurality of light emission devices arranged in a regular manner obtains the similar workings and effects.

### Configuration of Present Technology

The present technology has the following configuration. According to the present technology having the following configuration, it is possible to provide the light emission device and the image display apparatus that allow to effectively suppress or prevent the crosstalk and to improve the wavelength conversion characteristics.

(1)

A light emission device including:
a light emitting element having a light emission surface;
a first light controller that is formed on the light emission surface and controls at least one of a wavelength of light, a diffusion of light, or a direction of light;
a covering part that is formed on an opposite side to the light emission surface of the first light controller and covers and protects the first light controller; and
a first light shielding part that is formed on a side surface of the covering part and shields light.
   (2)

The light emission device according to (1), further including a second light shielding part that is formed on an opposite side to the light emission surface of the covering part, has a through opening that transmits light, and shields light emitted from the light emission surface.

(3)

The light emission device according to (2), in which a first reflection region that reflects light is disposed on at least a portion on a side of the first light controller of the second light shielding part.

(4)

The light emission device according to any one of (1) to (3), in which the light emitting element, the first light controller, and the covering part construct a first pixel.

(5)

The light emission device according to any one of (1) to (4), further including a second pixel including:
the light emitting element;
a second light controller that is formed on the light emission surface and controls at least one of a wavelength of light, a diffusion of light, or a direction of light different from the first light controller;
the covering part that is formed on an opposite side to the light emission surface of the second light controller and covers and protects the second light controller; and
the first light shielding part.
   (6)

The light emission device according to (5), further including: a third pixel including:
the light emitting element;
a third light controller that is formed on the light emission surface and controls at least one of a wavelength of light, a diffusion of light, or a direction of light different from each of the first light controller and the second light controller;
the covering part that is formed on an opposite side to the light emission surface of the third light controller and covers and protects the third light controller; and
the first light shielding part.
   (7)

The light emission device according to any one of (4) to (6), a fourth pixel including:
the light emitting element;
a transparent part that is formed on the light emission surface and does not control a wavelength of light,
the covering part that is formed on an opposite side to the light emission surface of the transparent part and covers and protects the transparent part, and
the first light shielding part.
   (8)

The light emission device according to (7), in which the transparent part includes a same material as the covering part.

(9)

The light emission device according to (6), in which a plurality of the first pixels, or the first pixel and the second pixel, or the first pixel, the second pixel, and the third pixel construct a single color pixel.

(10)

The light emission device according to (8), in which the first pixel and the fourth pixel construct a single color pixel.

(11)

The light emission device according to (6), further including a pixel separator that is formed along a side surface of the first light controller, the second light controller, or the third light controller and shields light.

(12)

The light emission device according to (7), further including a pixel separator that is formed along a side surface of the transparent part and shields light.

(13)

The light emission device according to (11) or (12), in which the pixel separator is extended to the side surface of the covering part and is formed as the first light shielding part.

(14)

The light emission device according to any one of (1) to (13), in which a second reflection region that reflects light is disposed at least on the side of the covering part of the first light shielding part.

(15)

The light emission device according to (2) or (3), in which the second light shielding part includes a same material as the first light shielding part.

(16)

The light emission device according to any one of (1) to (14), in which at least a portion of the first light shielding part has a lower refractive index than the covering part.

(17)

The light emission device according to any one of (1) to (14), in which at least a portion of the first light shielding part has a higher light absorptivity than the covering part.

(18)

The light emission device according to any one of (1) to (14), in which at least a portion of the first light shielding part on an opposite side to the light emission surface is a hardly-removable region that makes a process speed lower than a process speed of the covering part.

(19)

The light emission device according to any one of (1) to (14), in which the first light shielding part has an air gap.

(20)

The light emission device according to any one of (1) to (19), in which the covering part includes a stack having a plurality of different types of layers.

(21)

The light emission device according to any one of (1) to (20), in which a dielectric multi-layer film in which two or more types of dielectric bodies are stacked is formed on an opposite side to the light emission surface of the covering part.

(22)

The light emission device according to any one of (1) to (21), in which a color filter is formed on an opposite side to the light emission surface of the covering part.

(23)

The light emission device according to any one of (1) to (22), in which an optical path controller that controls an optical path is formed on an opposite side to the light emission surface of the covering part.

(24)

An image display apparatus that includes a plurality of arranged light emission devices, the light emission device comprising:
a light emitting element having a light emission surface;
a light controller that is formed on the light emission surface and controls at least one of a wavelength of light, a diffusion of light, or a direction of light;
a covering part that is formed on an opposite side to the light emission surface of the light controller and covers and protects the light controller; and
a light shielding part that is formed on a side surface of the covering part and shields light.

The present application claims the benefit of Japanese Priority Patent Application JP2022-026045 filed with the Japan Patent Office on Feb. 22, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A light emission device comprising:
a light emitting element having a light emission surface;
a first light controller that is formed on the light emission surface and controls at least one of a wavelength of light, a diffusion of light, or a direction of light;
a covering part that is formed on an opposite side to the light emission surface of the first light controller and covers and protects the first light controller; and
a first light shielding part that is formed on a side surface of the covering part and shields light.

2. The light emission device according to claim 1, further comprising a second light shielding part that is formed on an opposite side to the light emission surface of the covering part, has a through opening that transmits light, and shields light emitted from the light emission surface.

3. The light emission device according to claim 2, wherein a first reflection region that reflects light is disposed on at least a portion on a side of the first light controller of the second light shielding part.

4. The light emission device according to claim 1, wherein the light emitting element, the first light controller, and the covering part construct a first pixel.

5. The light emission device according to claim 4, further comprising a second pixel including:
the light emitting element;
a second light controller that is formed on the light emission surface and controls at least one of a wavelength of light, a diffusion of light, or a direction of light different from the first light controller;
the covering part that is formed on an opposite side to the light emission surface of the second light controller and covers and protects the second light controller; and
the first light shielding part.

6. The light emission device according to claim 5, further comprising a third pixel including:
the light emitting element;
a third light controller that is formed on the light emission surface and controls at least one of a wavelength of light, a diffusion of light, or a direction of light different from each of the first light controller and the second light controller;
the covering part that is formed on an opposite side to the light emission surface of the third light controller and covers and protects the third light controller; and
the first light shielding part.

7. The light emission device according to claim 4, further comprising a fourth pixel including:
the light emitting element;
a transparent part that is formed on the light emission surface and does not control a wavelength of light,
the covering part that is formed on an opposite side to the light emission surface of the transparent part and covers and protects the transparent part, and
the first light shielding part.

8. The light emission device according to claim 7, wherein the transparent part includes a same material as the covering part.

9. The light emission device according to claim 6, wherein a plurality of the first pixels, or the first pixel and the second pixel, or the first pixel, the second pixel, and the third pixel construct a single color pixel.

10. The light emission device according to claim 8, wherein the first pixel and the fourth pixel construct a single color pixel.

11. The light emission device according to claim 6, further comprising a pixel separator that is formed along a side surface of the first light controller, the second light controller, or the third light controller and shields light.

12. The light emission device according to claim 7, further comprising a pixel separator that is formed along a side surface of the transparent part and shields light.

13. The light emission device according to claim 11, wherein the pixel separator is extended to the side surface of the covering part and is formed as the first light shielding part.

14. The light emission device according to claim 1, wherein a second reflection region that reflects light is disposed at least on the side of the covering part of the first light shielding part.

15. The light emission device according to claim 2, wherein the second light shielding part includes a same material as the first light shielding part.

16. The light emission device according to claim 1, wherein at least a portion of the first light shielding part has a lower refractive index than the covering part.

17. The light emission device according to claim 1, wherein at least a portion of the first light shielding part has a higher light absorptivity than the covering part.

18. The light emission device according to claim 1, wherein at least a portion of the first light shielding part on an opposite side to the light emission surface is a hardly-removable region that makes a process speed lower than a process speed of the covering part.

19. The light emission device according to claim 1, wherein the first light shielding part comprises an air gap.

20. The light emission device according to claim 1, wherein the covering part includes a stack having a plurality of different types of layers.

21. The light emission device according to claim 1, wherein a dielectric multi-layer film in which two or more types of dielectric bodies are stacked is formed on an opposite side to the light emission surface of the covering part.

22. The light emission device according to claim 1, wherein a color filter is formed on an opposite side to the light emission surface of the covering part.

23. The light emission device according to claim 1, wherein an optical path controller that controls an optical path is formed on an opposite side to the light emission surface of the covering part.

24. An image display apparatus that includes a plurality of arranged light emission devices, the light emission device comprising:
a light emitting element having a light emission surface;
a light controller that is formed on the light emission surface and controls at least one of a wavelength of light, a diffusion of light, or a direction of light;
a covering part that is formed on an opposite side to the light emission surface of the light controller and covers and protects the light controller; and
a light shielding part that is formed on a side surface of the covering part and shields light.
